(19) United States
(12) Patent Application Publication
(10) Pub. No.: US 2007/0172603 A1
(43) Pub. Date: Jul. 26, 2007

(54) Process and Apparatus for Silicon Boat, Silicon Tubing and Other Silicon Based Member Fabrication

(76) Inventor: Kiril A. Pandelisev, Mesa, AZ (US)

Correspondence Address: CERMAK & KENEALY, LLP, 515 EAST BRADDOCK RD SUITE B, Alexandria, VA, 22314, US

(21) Appl. No.: 11/689,685

(22) Filed: Mar. 22, 2007

Related U.S. Application Data
(62) Division of application No. 10/804,152, filed on Mar. 19, 2004.
Application No. 10/804,152 is a continuation of application No. PCT/US02/29516, filed on Sep. 19, 2002.
(60) Provisional application No. 60/323,098, filed on Sep. 19, 2001.
(60) Provisional application No. 60/336,712, filed on Dec. 7, 2001.

(51) Int. Cl. C23C 16/24

(52) U.S. Cl. 427/588; 427/583; 427/589

(57) ABSTRACT

Process, apparatus, and application of a silicon/silicon alloy/silicon compound, having at least one silicon atom, to a boat, an epitaxial chamber, and tubing and liners, is described. Powder pressing, plasma and non plasma powder deposition, slurry deposition and slurry casting, silicon/silicon alloy casting and directional solidification are among methods useful for forming the devices. The articles have application in the wafer processing industry.

This application is a Divisional of, and claims priority under 35 U.S.C. § 120 to, U.S. application Ser. No. 10/804,152, filed Mar. 19, 2004, which was a Continuation of, and claimed priority under 35 U.S.C. § 120 to, International Application No. PCT/US02/29516, filed Sep. 29, 2002, and claims the benefit under 35 U.S.C. § 119 therethrough to U.S. Provisional Application No. 60/323,098, filed Sep. 19, 2001, and U.S. Provisional Application No. 60/336,712, filed Dec. 7, 2001.

### BACKGROUND

Wafer Boats and wafer holders made from high purity quartz, fused silica or silicon carbide are being used in silicon and other wafer processing. Some processing is done in quartz-lined stainless steel chambers. As the device size becomes smaller the mismatch between the thermal properties of the silicon wafer, the wafer boat housing the wafer during various chemical and thermal treatments and the chamber housing the boat with the wafers becomes a problem.

Particulates are created and the stress imposed on the wafer during various processing steps affects the yield of the process. New approaches to the process environment are needed.

### SUMMARY

According to a first aspect of the invention, a process of manufacturing at least one electronic chip comprises (a) selecting a fabrication material from the group consisting of silicon, silicon compound comprising at least one silicon atom and in which silicon is a majority, silicon and germanium, Siₓ₁Ge₁₋ₓ₁ solid solution, wherein 0≦X1≦1, silicon and silicon carbide Siₓ₂(SiC)₁₋ₓ₂, wherein 0.3≦X2≦1, silicon and silicon dioxide Siₓ₃(SiO₂)₁₋ₓ₃, wherein 0<X3<1, silicon and a ceramic and in which silicon is the majority material, silicon and an oxide Siₓ₄(Oxide)₁₋ₓ₄, wherein 0≦X4≦1, silicon and a metal Siₓ₅M₁₋ₓ₅, wherein 0≦X5≦1, silicon and a metal alloy Siₓ₆A₁₋ₓ₆, wherein 0≦X5≦1, and combinations thereof; forming at least a portion of a wafer processing chamber from the fabrication material using a process selected from the group consisting of forging, extrusion, plasma deposition, hot substrate powder deposition, powder deposition, CVD deposition, slurry spray, slurry processing, casting, gelcasting, directional solidification, crystal growth, powder processing, and combination thereof; placing a wafer in the chamber and on the wafer processing member at least for a period of time that the wafer is in the chamber; processing the wafer in the chamber; removing the wafer from the chamber; and processing the wafer to form at least one electronic chip comprising one or more electronic devices.

These and further and other aspects and features of the invention are apparent in the disclosure, which includes the above and ongoing written specification, with the claims and the drawings.

### BRIEF DESCRIPTION OF THE DRAWINGS

FIG. 1. Reshaping/Forging silicon/silicon alloy/composite material.

FIG. 2. High temperature vacuum/special gas atmosphere reshaping/forging silicon/silicon alloy/composite material.

FIG. 3. Extrusion Apparatus with refill hopper.

FIG. 4. High temperature vacuum/special gas atmosphere extrusion apparatus.

FIG. 5. Material deposition via powder only and/or plasma heated powder spray deposition of silicon/silicon alloy/composite.

FIG. 6. Silicon/silicon alloy/composite slurry deposition

FIG. 7. Directional solidification fabrication of tubing used as a liner or for fabrication of wafer boat.

FIG. 8. Solid and shaped tubing for fabrication of wafer boat.

FIG. 9. Semi fabricated silicon/silicon alloy/composite wafer processing boat.

FIG. 10. Semi fabricated wafer processing boat made from structurally reinforced silicon/silicon alloy/composite material.

FIG. 11. Cross section of the base material for wafer processing boat made from structurally reinforced silicon/silicon alloy/composite material.

FIG. 12. Schematic diagram for making tubing and wafer processing fabricates thereof from casting silicon/silicon alloy/composite powder.

FIG. 13. Schematic diagram for making tubing and wafer processing fabricates thereof by cold/hot pressing silicon/silicon alloy/composite powder.

FIG. 14. Schematic diagram for making tubing, plate or rod and wafer processing fabricates thereof from pressing silicon/silicon alloy/composite powder.

FIG. 15. Vertical CVD chamber lined with employing silicon/silicon alloy/composite material employing silicon/silicon alloy/composite wafer boat.

FIG. 16. Multi-chamber wafer processing system employing at least one silicon lined chamber and silicon equipped chamber.

FIG. 17. Top and side view of epitaxial/CVD chamber fabrication process.

FIG. 18. Top view of a multi-chamber wafer processing system employing at least one silicon made chamber and silicon equipped chamber.

FIG. 19. Side view of a multi-chamber epitaxial wafer processing system employing at least one silicon made chamber and silicon equipped chamber.

FIG. 20. Germanium-Silicon phase diagram.

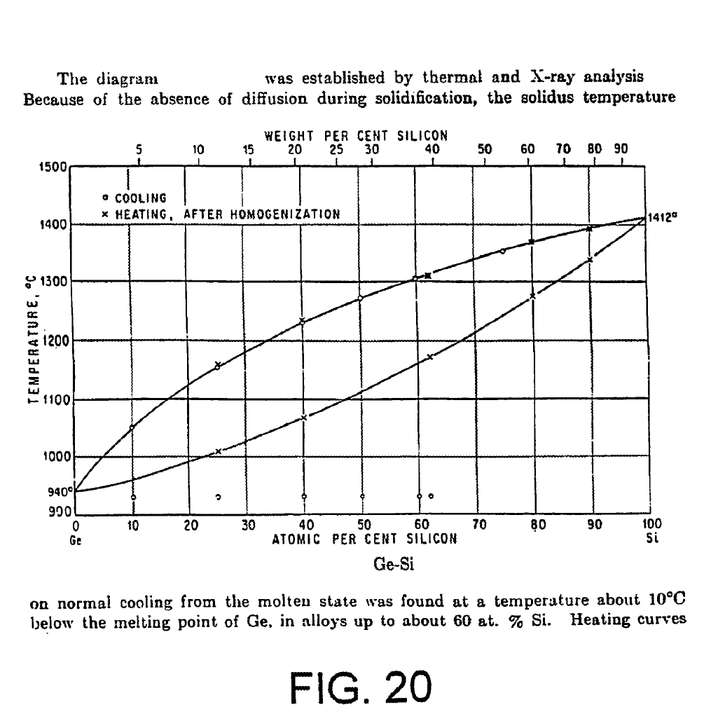

### DETAILED DESCRIPTION OF EXEMPLARY EMBODIMENTS

High purity quartz or fused silica is used as material for various epitaxial reactors, CVD chambers, CVD chamber liners and/or tubing for processing the wafers. Silicon boats made from single crystalline silicon only will not have the desired mechanical properties. Single crystal silicon considerably softens at 400° C. and makes it not suitable for many high temperature applications. The present invention provides a solution to those and other problems.

Processes and apparatus for various approaches for making various silicon/silicon alloy members are described below. Forging, extrusion, plasma and hot substrate powder deposition, slurry spray and slurry casting, silicon/silicon alloy casting and directional solidification is described here in more detail. Other methods modified for silicon member fabrication may be used for fabrication of the same.

Silicon/Silicon Alloy Powder Pressing/Forging and Extrusion

Silicon/Silicon Alloy Powder Pressing/Forging and Extrusion may be employed for fabrication of various silicon/silicon alloy members that include, but is not limited to, wafer boats for horizontal and vertical wafer processing furnaces and deposition chambers, epitaxial reactors, lining for CVD, epitaxial reactors and other wafer processing tools, and tubing having any form or cross section shape.

Silicon/silicon alloy powder is pressed at room temperature or at an elevated temperature in vacuum or in a controlled atmosphere. Outgassing, removal of oxygen, nitrogen, water vapor, and removal of other undesired gases may also be effected before the pressing of the powder. The powder is pressed to a near shape of the part being fabricated, or it may be pressed into a raw material for further processing of the same. The powder consists of silicon, silicon and germanium, silicon and any metal, silicon and silicon carbide, silicon and any ceramic, or silicon and any suitable element or compound.

Silicon powder, silicon based alloys or other suitable silicon or nonsilicon based materials, and/or composites having the desired grain size, is placed in a pressing chamber. The compound may or may not contain silicon alloy. After proper gas treatment and/or vacuuming of the residual gas, the powder is pressed. The pressing temperature may be as low as room temperature or as high as the softening point of the lowest melting point constituent. Such pressed part is later on sintered in a vacuum or an appropriate gaseous atmosphere. Very dense materials having predetermined hardness results from this process. Knowing that the fracture strength is inversely proportional to the grain size (the smaller the grain size, the higher the fracture strength) one may tailor various parts for various applications.

Parts made by this process may be machined before the sintering (green part machining). After the sintering process they are expected to yield near shape and they may be used as they are or may be subjected to final machining.

Pressures of up to 800,000 psi or higher may be used for this process. The temperature of the material during pressing and sintering may vary depending on the composition. Temperatures between 300° C. and 1350° C. may be used. Lower than 300° C. and higher than 1350° C. may also be used depending on the material processed and the properties desired.

If press-shaping solid silicon (single crystal or polycrystalline material) into various parts the silicon is heated to the desired temperature for the appropriate plastic properties. The shaping may be done using forging or extrusion of the silicon/silicon alloy or other alloy material.

Pressing and shaping of the material may be done before, during or after the sintering of the material. The plasticity of the material may determine the grain size and the fracture strength of the same. Several steps of hot press process may be employed. For instance, extrusion may be followed by forging and/or high pressure annealing.

The shaping of the material may be used for imbedding stronger material in the part itself for reinforcement purposes. The strong layer may be within the part or may constitute the outer or inner surface of the part. Parts having desired strength pattern may be made by this method.

Powder Deposition

Plasma heated silicon grain is introduced in a chamber that may be a vacuum, low pressure, normal pressure, medium pressure, or high-pressure chamber. The so heated powder is directed towards a heated substrate and deposited. The powder deposition may consist of silicon only, or silicon and other material particles that might reinforce the silicon structure without changing the chemical behavior, or material particles that change the properties of silicon and form a silicon alloy or a solid solution that may or may not contain any silicon. Ge, SiG₁₋ₓ, SiC, other silicon based materials or ceramics, or other suitable elements or compounds that contain no silicon or silicon alloys may be used for doping, reinforcement purposes, or as main materials for the part being made. Depending on the temperature of the substrate, the deposited layers may have different densities and thicknesses which after sintering results in very dense material having desired fracture strengths.

Non-plasma heated powder or non-heated powder may be injected into the chamber and directed towards a hot substrate within heated or non-heated controlled atmosphere or vacuum chamber. The powder grain is heated to the desired temperature on its way to the substrate and from the hot substrate. Such heated grain adheres to the substrate and/or other previously deposited grains. The density of the deposited body depends greatly on the grain size, grain temperature at impact, and the substrate temperature.

The silicon/silicon alloy/composite member made may have any shape: rod, tube having any cross-section and shape, or any chamber looking type shape where there may be one or more gates. The substrate may be heated up to the softening point of silicon. Optimal temperature is expected to be, but not limited to, between 800° C. to 1350° C. Temperatures less than 800° C. and more than 1350° C. may also be applied.

The sintering of the silicon/silicon alloy/composite members may be done in situ, or after they have been machined, shaped or joined with other parts made by the same or different process. The sintering temperature will greatly depend on the chemical composition of the parts and their applications.

CVD Deposition

CVD deposition of any type may be used for deposition of silicon and/or silicon and other materials that provides for reinforcement of the deposited layers without changing the chemical behavior of the surface of interest. The silicon/silicon alloy/composite layers may be on a suitable substrate that has sticking coefficient to the deposited material. Silicon nitrides, graphite, metal silicates, some ceramics, such as SiC, and other combinations may be suitable as substrate for particular applications.

The temperature of the substrate, as well as the pressure of the deposition process, may vary depending on the method used. So, deposited layers may have an initial thickness that after sintering results in a very dense material having a desired thickness for a particular application. Silicon/silicon alloy/composite members having the shape of a rod, a tube having; desired cross-section shape and size, a plate, or any wafer processing chamber suitable type shape may be made. There might be one or more gates leading inside the chamber.

Slurry Method and Apparatus

Mixing the powder with a high purity liquid chemical compound and forming a slurry for spraying or casting of desired body may be also be employed. In the case of spraying, the slurry is deposited on a substrate that may rotate or translate. The substrate may be any material that does not react with or contaminate the slurry and that can either be incorporated in the product made or it can be separated after the removal of the liquid by curing during or after the deposition of the slurry. Such cured articles can be roughly machined before the bake-out process. A bake out process is employed to completely remove the chemical substance (binder) and to sinter the silicon/silicon alloy/composite powder made member. Machining of these parts into desired shapes follows the bake-out process.

The slurry deposition and/or casting may be conducted in vacuum or controlled gas atmosphere chamber employing one or more heaters. The curing and sintering may be conducted in the same or in a different chamber.

Silicon/silicon alloy members having shapes of a rod, a round tube, a rectangular tube, a plate, or any wafer processing chamber suitable type shape may be made by this approach.

Casting

Casting to shape a silicon/silicon alloy/composite grain, or re-melting and casting solid silicon, may be used for forming various alloy made parts. A high purity mold made from easily removable material that does not react with silicon/silicon alloy/composite is filled with shot, powder or small chunks of the material to be processed. The material used for casting may be melted in a separate container and transferred into the mold after melting. All appropriate steps for removal of the oxygen, nitrogen, water vapor, and other possible contaminants are taken before the processing takes place. The silicon/silicon alloy/composite member made may have any shape: rod, round tube, tube or any other shape or form.

Gelcasting of Silicon/Silicon Alloy/Composite Material Members

During gelcasting of the Silicon/Silicon Alloy/Composite Material, the material is first converted in powder having a desired grain size. The powder is suspended in a monomer solution which is polymerized in a mold to form a rigid polymer/solvent gel. Organic or inorganic substances might be added to the powder/polymer binder to trigger the polymerization process at desired process conditions such as temperature, viscosity, etc. The system may contain up to 10-20 weight % polymer. This percentage may be as low as a few weight percent and may be over 20 weight percent. The solvent portion is removed by a drying step after the part is removed from the mold.

The solution may be aqueous or non-aqueous. Typical non-aqueous solutions might contain 50-55 volume % of powder with the balance being the dispersion solution. The solution may have about 10% dispersant, such as Rohm & Haas Triton X-100, or N-100 Dupont dibasic ester (DBE) or ICI Americas Solsperse 2000 in dibutil phtalate (DBP) and 90% gelcasting premix. The premix might include 10-30 volume % of monomers such as trifunctional trimethilpropane triacrylate (TMPTA) and difunctional 1,6 hexanediol diacrilate (HDODA) both from Hoechst Celanese, 0.5 to 10 volume % of dybenzoil peroxide initiator with the rest being either DBA, DBP or other suitable solvent.

The member fabrication may be done by hardening of the mass in a mold, by spraying onto a substrate having desired process temperature. The spraying might be vacuum or desired gaseous atmosphere. The spraying method may include spraying the slurry or spraying the various components onto the substrate where they mix, react, and harden into the desired shape.

The member fabrication may be by continuous feed onto a beltline type apparatus. Hardening, drying, and even sintering may be part of the continuous process. The feed may include an already made mixture, or mixing it at the feeding point.

Directional Solidification

Fabrication of large size silicon/silicon alloys/composite in a plate, rod, tube or any other shape might be made economical by the use of directional solidification. The process may be carried out in an open or closed mold/container containing the material to be solidified. The process may be conducted in a vacuum or a controlled atmosphere chamber. All appropriate steps for removal of oxygen, nitrogen, water vapor, and other possible contaminants are taken before the processing takes place. The member made may have any shape: plate, rod, tube or any other shape or form.

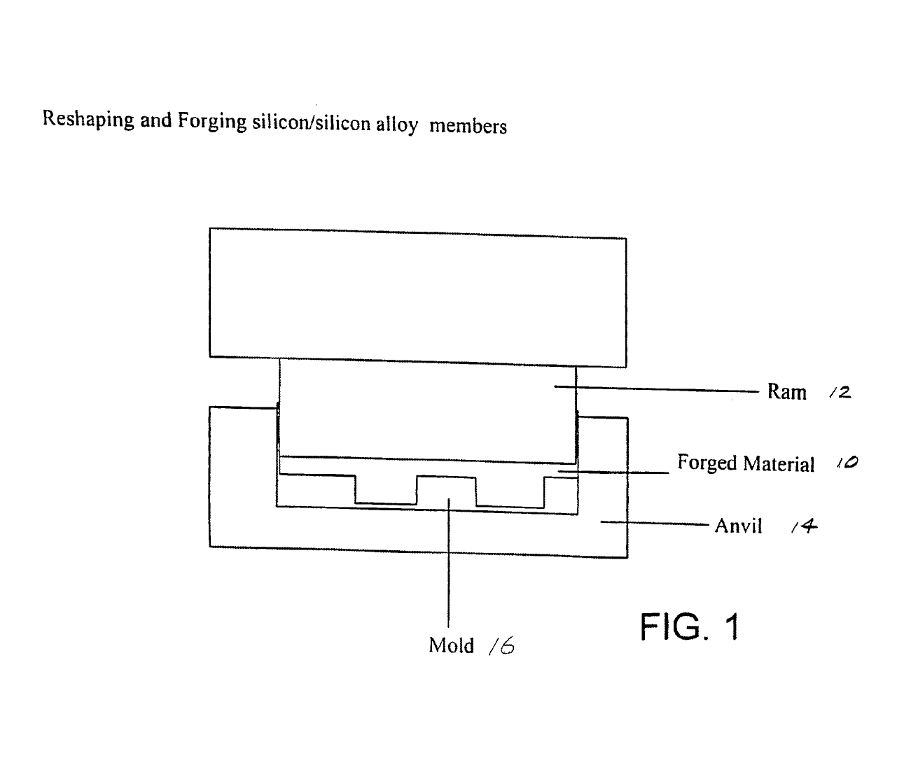

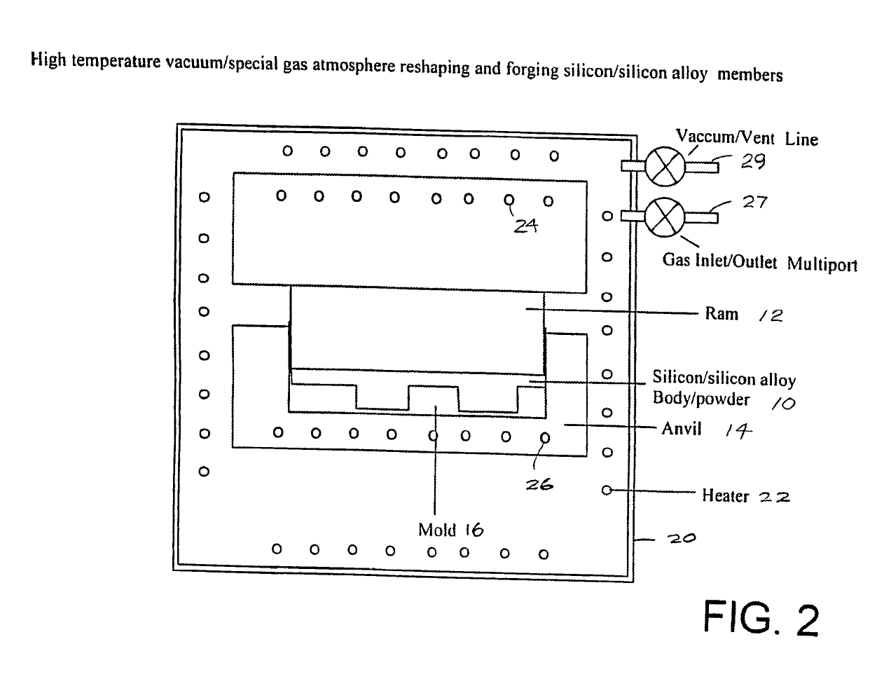

Referring to FIGS. 1 and 2, powder is forged into body 10 with a ram 12, anvil 14 and mold 16. In FIG. 2, heated enclosure 20 has a heater 22, a ram heater 24 and an anvil heater 26. A gas inlet/outlet multiport 27 supplies chamber 20. A vacuum/vent line 29 removes gases.

Forging the monocrystal body uses a temperature between 400° C. and near the melting point. The temperature may be less than 400° C. or several degrees less than the melting point of the lowest melting phase in the crystal.

Forging the monocrystal body uses a temperature of 400° C.

Forging the monocrystal body uses a temperature of 600° C.

Forging the monocrystal body uses a temperature of 800° C.

The forged body 10 is polycrystalline material.

The forged body is amorphous material.

The forged body may be composed of single crystalline portion and polycrystalline portion and amorphous portion.

The forging is in vacuum, reduced pressure or inert atmosphere having a desired pressure.

The forging is in vacuum, reduced pressure or reactive atmosphere having desired pressure.

The reactive atmosphere in chamber 20 may be plasma, reactive gases, or solid, and the process of purification is administered.

Forging powder for body 10 consists of silicon, silicon and germanium, SiₓGe₁₋ₓ solid solution, silicon and Silicon Carbide Siₓ(SiC)₁₋ₓ, Silicon and silicon dioxide Siₓ(SiO₂)₁₋ₓ, silicon and any ceramic, silicon and any oxide Siₓ(Oxide)₁₋ₓ, silicon and any metal SiₓM₁₋ₓ, Silicon and any alloy SiₓA₁₋ₓ, any combination between themselves at temperature equal or greater than room temperature and lower than the melting point of one or more constituents of the pressed body R_{T}≦T≦T_{M}.

The temperature may be 400° C.≦T≦800° C.

The temperature may be 200° C.≦T≦1000° C.

The temperature may be 200° C.≦T≦1200° C. The temperature may be smaller than 200° C. or greater than 1200° C.

The forging is in vacuum, reduced pressure or inert atmosphere having desired pressure.

The forging is in vacuum, reduced pressure or reactive atmosphere having desired pressure.

The reactive atmosphere may be plasma, reactive gases, or solid, and a process of purification is administered.

The powder may be silicon powder or shot having various grain sizes from sub-micron to rather large shot sizes of several millimeters or larger.

The powder may be silicon powder and germanium powder or shot having various grain sizes from sub-micron to rather large shot sizes of several millimeters or larger.

The powder may be silicon powder and SiₓGe₁₋ₓ (0≦x≦1) powder or shot having various grain sizes from sub-micron to rather large shot sizes of several millimeters or larger.

The powder may be silicon powder and silicon carbide, Siₓ(SiC)₁₋ₓ (0≦x≦1) powder or shot having various grain sizes from sub-micron to rather large-shot sizes of several millimeters or larger.

The powder may be silicon powder and silicon dioxide, Siₓ(SiO₂)₁₋ₓ, (0≦x≦1) powder or shot having various grain sizes from sub-micron to rather large shot sizes of several millimeters or larger.

The powder may be silicon powder and metal, SiₓM₁₋ₓ (0≦x≦1) powder or shot having various grain sizes from sub-micron to rather large shot sizes of several millimeters or larger.

The powder may be silicon powder and Siₓ(Alloy)₁₋ₓ (0≦x≦1) powder or shot having various grain sizes from sub-micron to rather large shot sizes of several millimeters or larger.

The powder may be silicon powder and/or metal and/or ceramic and/or alloy and/or oxide and/or any suitable additive powder or shot having various grain sizes from sub-micron to rather large shot sizes of several millimeters or larger.

The powder can be any material suitable for the member fabrication.

The forging apparatus may consist of anvil, mold that contains the forged body and ram.

Each part may be independently heated.

The forging apparatus may be heated from all sides.

The forging apparatus may be enclosed fully or partially in a vacuum, reduced pressure or desired pressure chamber that may be filled with inert, reactive gas or plasma gas.

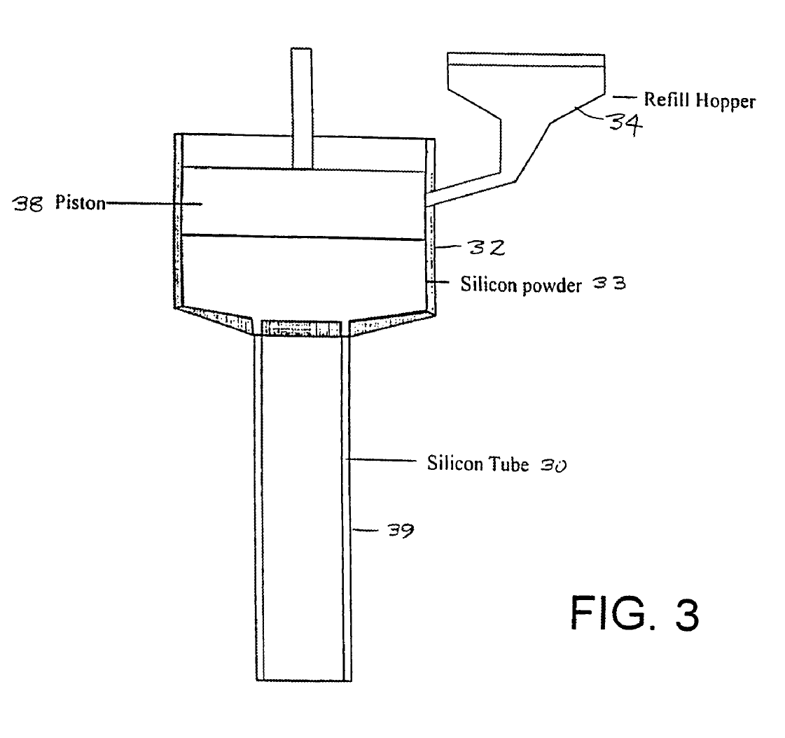

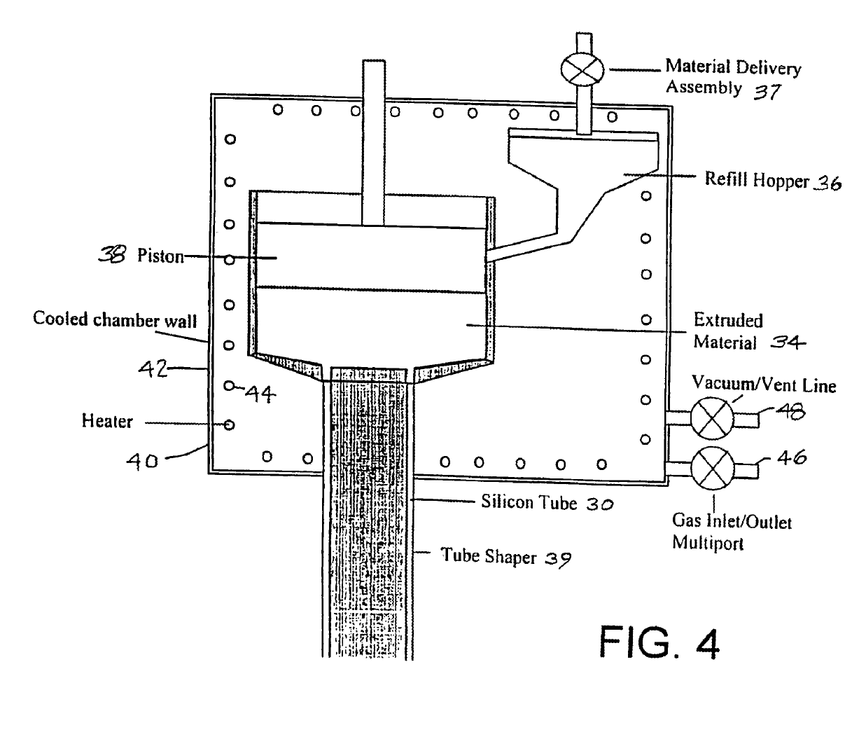

FIGS. 3 and 4 show extruding a monocrystal tubular body 30 having a temperature between 400° C. and near the melting point. The temperature might be less than 400° C. or several degrees less than the melting point of the lowest melting phase in the crystal.

Extrusion chamber 32 holds silicon powder 33, which becomes the extruded material 34, delivered by refill hopper 36 from a material delivery assembly 37. The extruded body 30 is forced by piston 38 through a tube shaper 39. A surrounding chamber 40 has a cooled wall 42 and an internal heater 44, a gas inlet/outlet multiport 46, and a vacuum/vent line 48.

The material being extruded may be a single crystal, polycrystalline chunks of material or powder including silicon/silicon alloy/composite material.

Extruding a monocrystal body uses a temperature of 400° C.

Extruding a monocrystal body uses a temperature of 600° C.

Extruding a monocrystal body uses a temperature of 800° C.

The extruded body is polycrystalline material.

The extruded body is amorphous material.

The extruded body may be composed of single crystalline portion and polycrystalline portion and amorphous portion.

The extruding is in vacuum, reduced pressure or inert atmosphere having desired pressure.

The extruding is in vacuum, reduced pressure or reactive atmosphere having desired pressure.

The reactive atmosphere may be plasma, reactive gases, or solid, and a process of purification is administered.

Extruding powder 33 consists of silicon, silicon and germanium, SiₓGe₁₋ₓ solid solution, silicon and Silicon Carbide Siₓ(SiC)₁₋ₓ, Silicon and silicon dioxide Siₓ(SiO₂)₁₋ₓ, silicon and any ceramic, silicon and any oxide Siₓ(Oxide)₁₋ₓ, silicon and any metal SiₓM₁₋ₓ, Silicon and any alloy SiₓA₁₋ₓ, any combination between themselves at temperature equal or greater than room temperature and lower than the melting point of one or more constituents of the pressed body R_{T}≦T≦T_{M}.

The temperature may be 400° C.≦T≦800° C.

The temperature may be 200° C.≦T≦1000° C.

The temperature may be 200° C.≦T≦1200° C. The temperature may be smaller than 200° C. or greater than 1200° C.

The extruding is in vacuum, reduced pressure, or an inert atmosphere having desired pressure.

The extruding is in vacuum, reduced pressure, or a reactive atmosphere having desired pressure.

The reactive atmosphere may be plasma, reactive gases, or solid, and a process of purification is administered.

The powder may be silicon powder or shot having various grain sizes from sub-micron to rather large shot sizes of several millimeters or larger.

The powder may be silicon powder and germanium powder or shot having various grain sizes from sub-micron to rather large shot sizes of several millimeters or larger.

The powder may be silicon powder and SiₓGe₁₋ₓ (0≦x.≦1) powder or shot having various grain sizes from sub-micron to rather large shot sizes of several millimeters or larger.

The powder may be silicon powder and silicon carbide, Siₓ(SiC)₁₋ₓ (0≦x≦1) powder or shot having various grain sizes from sub-micron to rather large shot sizes of several millimeters or larger.

The powder may be silicon powder and silicon dioxide, Siₓ(SiO₂)₁₋ₓ (0≦x≦1) powder or shot having various grain sizes from sub-micron to rather large shot sizes of several millimeters or larger.

The powder may be silicon powder and metal, SiₓM₁₋ₓ (0≦x≦1) powder or shot having various grain sizes from sub-micron to rather large shot sizes of several millimeters or larger.

The powder may be silicon powder and Siₓ(Alloy)₁₋ₓ (0≦x≦1) powder or shot having various grain sizes from sub-micron to rather large shot sizes of several millimeters or larger.

The powder may be silicon powder and/or metal and/or ceramic and/or alloy and/or oxide and/or any suitable additive powder or shot having various grain sizes from sub-micron to rather large shot sizes of several millimeters or larger.

The extruding apparatus may include of an anvil, a mold that contains the forged body, and a ram.

Each part may be independently heated.

The extruding apparatus may be heated from all sides.

The extruding apparatus may be enclosed fully or partially in a vacuum, reduced pressure or desired pressure chamber that may be filled with inert, reactive gas or plasma gas.

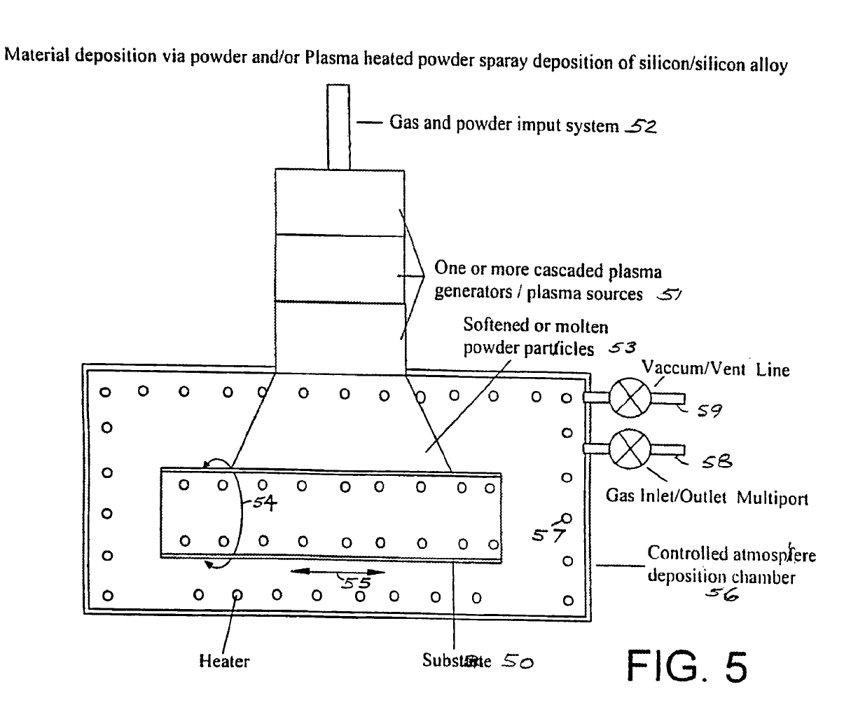

FIG. 5 shows material deposition on a substrate 50, in this case a hollow tube, from plasma generators or sources 51 supplied by a gas and powder input system 52. Plasma heated softened particles 53 strike and stick to the substrate and form layers as they are rotated 54 and translated 55. A chamber 56 surrounding the deposition is heated 57. Gas inlet/outlet multiport 58 and vacuum/vent line 59 are connected to the chamber.

Plasma deposition apparatus 59 includes one or more plasma generators or plasma sources, a gas input system, a powder input system, a vacuum chamber, with or without one or more chamber heating elements, and a substrate with/out heating elements.

The chamber may have one or more deposition ports.

The substrate may have rotation and/or translation mechanisms.

The chamber may have rotation and/or translation mechanisms.

Plasma assisted deposition of powder is performed, including silicon, silicon and germanium, SiₓGe₁₋ₓ solid solution, silicon and Silicon Carbide Siₓ(SiC)₁₋ₓ, Silicon and silicon dioxide Siₓ(SiO₂)₁₋ₓ, silicon and any ceramic, silicon and any oxide Siₓ(Oxide)₁₋ₓ, silicon and any metal SiₓM₁₋ₓ, Silicon and any alloy SiₓA₁₋ₓ, and any combination between themselves, at temperature equal to or greater than room temperature and lower than the melting point of one or more constituents of the deposited body R_{T}≦T≦T_{M}.

The deposition process occurs under vacuum, reduced pressure, reactive atmosphere, inert gas, plasma, and any combinations thereof.

The deposition process is in an atmosphere having desired pressure.

The reactive atmosphere may be plasma, reactive gases, or solid, and a process of purification is administered.

The temperature in the chamber may be between a temperature equal or greater than room temperature and lower than the melting point of one or more constituents of the deposited body R_{T}≦T≦T_{M}.

The temperature in the chamber may be 400° C.≦T≦800° C.

The temperature in the chamber may be 200° C.≦T≦1000° C.

The temperature in the chamber may be 200° C.≦T≦1200° C. The temperature may be smaller than 200° C. or greater than 1200° C.

The temperature of the substrate may be between a temperature equal or greater than room temperature and lower than the melting point of one or more constituents of the deposited body R_{T}≦T≦T_{M}.

The temperature of the substrate may be 400° C.≦T≦800° C.

The temperature of the substrate may be 200° C.≦T≦1000° C.

The temperature of the substrate may be 200° C.≦T≦1200° C. The temperature may be smaller than 200° C. or greater than 1200° C.

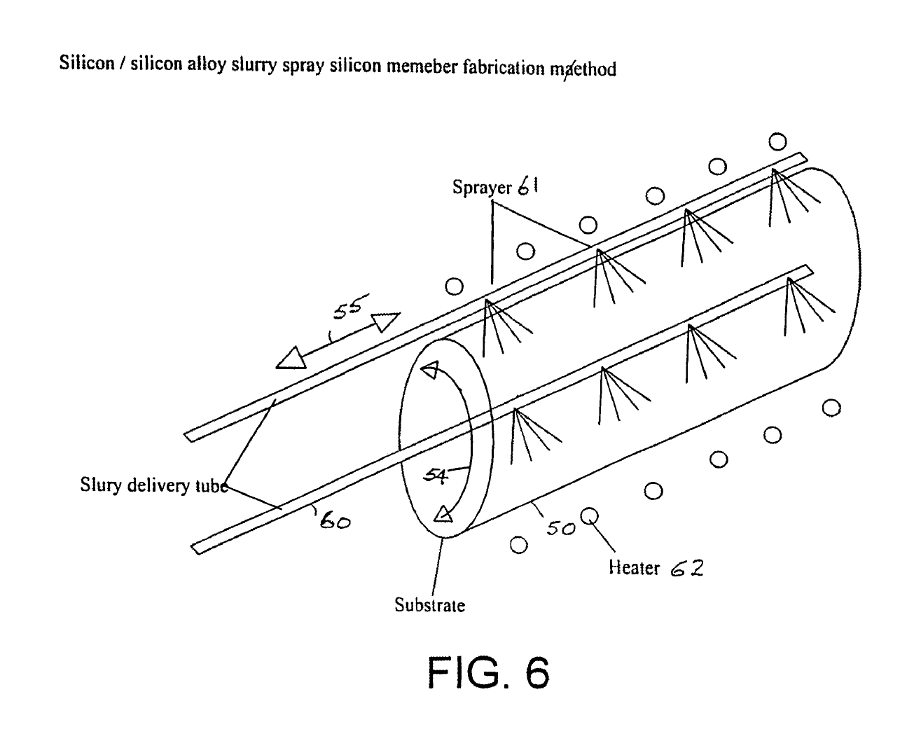

In FIG. 6, substrate 50 is rotated 54. The substrate or slurry delivery tubes 60 translate 55 sprayer 61 spray heated powder which is heated and softened by heaters 62.

Deposition apparatus for spraying of powder, powder and organic or inorganic base material, powder and gaseous material: the powder may consist of silicon, silicon and germanium, SiₓGe₁₋ₓ solid solution, silicon and Silicon Carbide Siₓ(SiC)₁₋ₓ, silicon carbide, silicon nitride, silicon oxynitride, any silicon compound, Silicon and silicon dioxide Siₓ(SiO₂)₁₋ₓ, silicon and any ceramic, silicon and any oxide Siₓ(Oxide)₁₋ₓ, silicon and any metal SiₓM₁₋ₓ, Silicon and any alloy SiₓA₁₋ₓ, and any combination between themselves, at a temperature equal to or greater than room temperature and lower than the melting point of one or more constituents of the deposited body R_{T}≦T≦T_{M}, including a substrate, a plurality of sprayers positioned to spray at least one portion of one side, and heating elements capable of heating the substrate at least from one side.

The substrate may be tubular, having any cross-section, planar, or have any desired shape or form suitable for the particular application.

The substrate may be rotated and translated.

The substrate may be heated from inside and/or outside.

The sprayers may be one or more and they may be oscillated, rotated and translated in relations to themselves and to the substrate the deposition takes place on.

The apparatus may be enclosed in vacuum, reduced pressure or any process suitable chamber that may have vacuum and vent valves and gas delivery system.

The deposition process may be under vacuum, reduced pressure, reactive gas, inert gas, plasma, and any combinations thereof.

The process is in atmosphere having desired pressure.

The reactive atmosphere may be plasma, reactive gases, or solid, and a process of purification is administered.

The temperature in the chamber may be between a temperature equal to or greater than room temperature and lower than the melting point of one or more constituents of the deposited body R_{T}≦T≦T_{M}.

The temperature in the chamber may be 400° C.≦T≦800° C.

The temperature in the chamber may be 200° C.≦T≦1000° C.

The temperature in the chamber may be 200° C.≦T≦1200° C. The temperature may be smaller than 200° C. or greater than 1200° C.

The temperature of the substrate may be between temperature equal or greater than room temperature and lower than the melting point of one or more constituents of the deposited body R_{T}≦T≦T_{M}.

The temperature of the substrate may be 400° C.≦T≦800° C.

The temperature of the substrate may be 200° C.≦T≦1000° C.

The temperature of the substrate may be 200° C.≦T≦1200° C. The temperature may be smaller than 200° C. or greater than 1200° C.

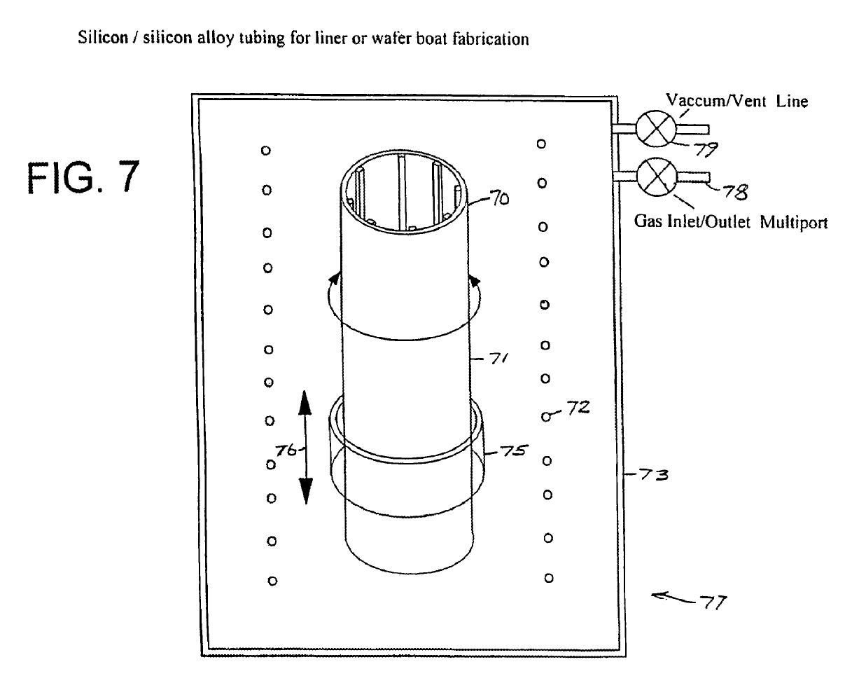

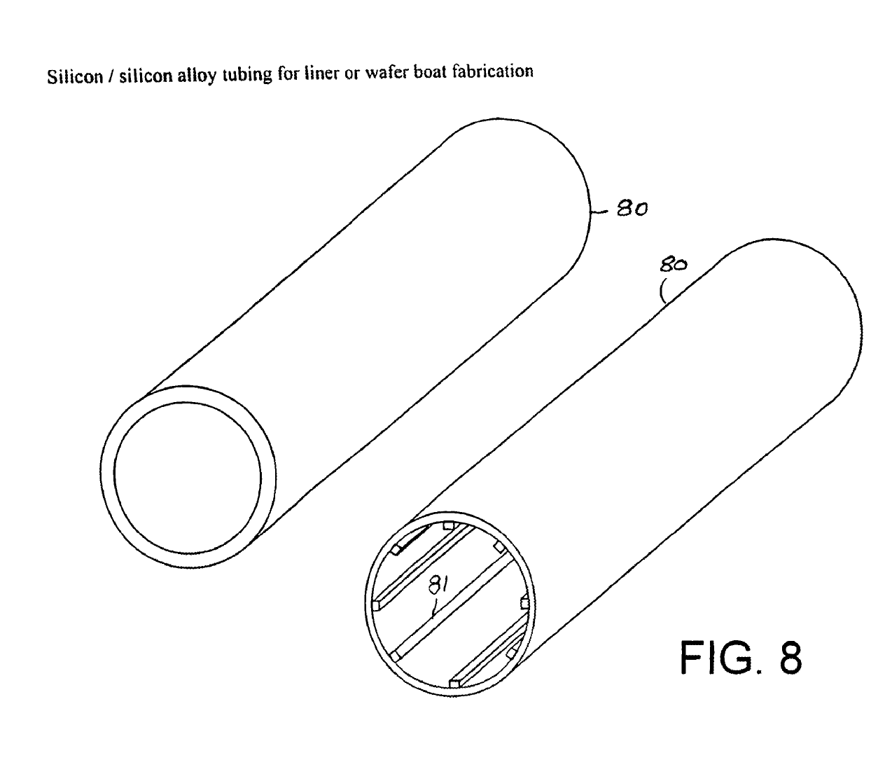

In FIGS. 7 and 8, a silicon preform 71 is placed in a heated 72 chamber 73. The preform is rotated 74 and a heated ring 75 is translated 76 along the preform for sintering and/or melting the material and forming a solid product.

Apparatus 77 for making tubular members 71 has any cross section and length and any other desired shape or form, including a mold 70 filled with a desired material and a heater 75 covering part of this mold and a chamber 73 fully or partially surrounding the member 71 and the heating elements 72. The chamber has a gas inlet/outlet, multiport 78 and a vacuum/vent line 79.

The chamber is a vacuum, low pressure, or pressure chamber.

In one embodiment, there is no chamber surrounding the member and the heating elements.

The member can be rotated and/or translated.

The member can be heated from the inside and/or outside.

The member can be heated from outside by chamber heaters 72 and a zone heater 75 for directional or non-directional processing.

The chamber has vacuum and/or vent valves 79.

The chamber has a gas inlet/outlet multiport 78.

The chamber has one or more plasma source(s) attached.

The material processed is solid material, powder, powder and organic or inorganic base material, or powder and gaseous material. The powder may consist of silicon, silicon compound comprising at least one atom of silicon, silicon and germanium, SiₓGe₁₋ₓ solid solution, silicon and Silicon Carbide Siₓ(SiC)₁₋ₓ, Silicon and silicon dioxide Siₓ(SiO₂)₁₋ₓ, silicon and any ceramic, silicon and any oxide Siₓ(Oxide)₁₋ₓ, silicon and any metal SiₓM₁₋ₓ, Silicon and any alloy SiₓA₁₋ₓ, and any combination between themselves, at a temperature equal to or greater than room temperature and lower than the melting point of one or more constituents of the deposited body R_{T}≦T≦T_{M}, including a substrate, a plurality of sprayers positioned to spray at least one portion of one side, and heating elements capable to heat the substrate at least from one side.

The substrate may be tubular, having any cross-section, planar or have any desired shape or form suitable for the particular application.

The processing of the material may be under vacuum, reduced pressure, reactive gas, inert gas, plasma, and any combinations thereof.

The processing of the material is in inert atmosphere having desired pressure.

The reactive atmosphere may be plasma, reactive gases or solid, and a process of purification is administered.

The process temperature may be between a temperature equal to or greater than room temperature and lower than the melting point of one or more constituents of the deposited body R_{T}≦T≦T_{M}.

The process temperature may be 400° C.≦T≦800 ° C.

The process temperature may be 200° C.≦T≦1000° C.

The process temperature may be 200° C.≦T≦1200° C. The temperature may be smaller than 200° C. or greater than 1200° C.

The temperature of the substrate may be between a temperature equal to or greater than room temperature and lower than the melting point of one or more constituents of the deposited body R_{T}≦T≦T_{M}.

The temperature of the substrate may be 400° C.≦T≦800° C.

The temperature of the substrate may be 200° C.≦T≦1000° C.

The temperature of the substrate may be 200° C.≦T≦1200° C. The temperature may be smaller than 200° C. or greater than 1200° C.

The member may be tubular and have any cross section such as round, elliptical, rectangular, polygonal, or any other shape.

The member may have an uneven thickness pattern over its entire surface.

The member may have different composition and density over the entire body.

The member may have different composition and density over its thickness.

The composition and material properties may be layered over any of the dimensions of the member such as its length, thickness, width, radius, etc.

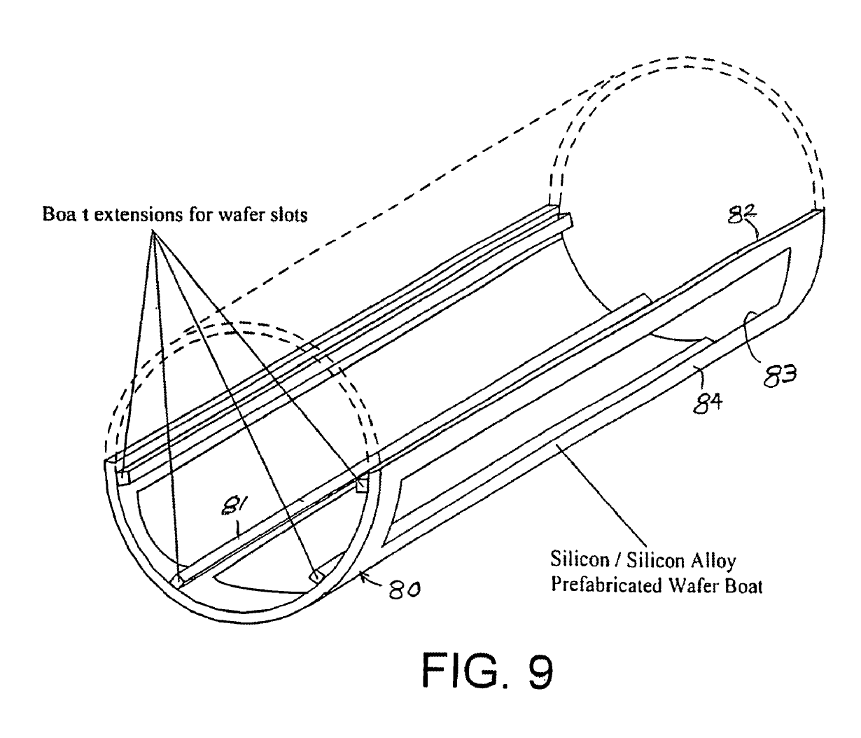

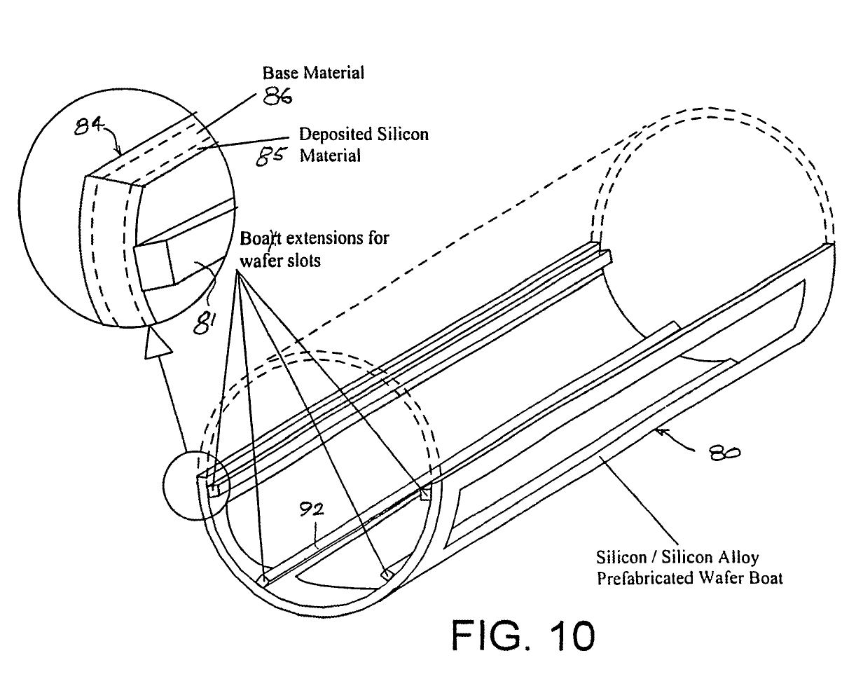

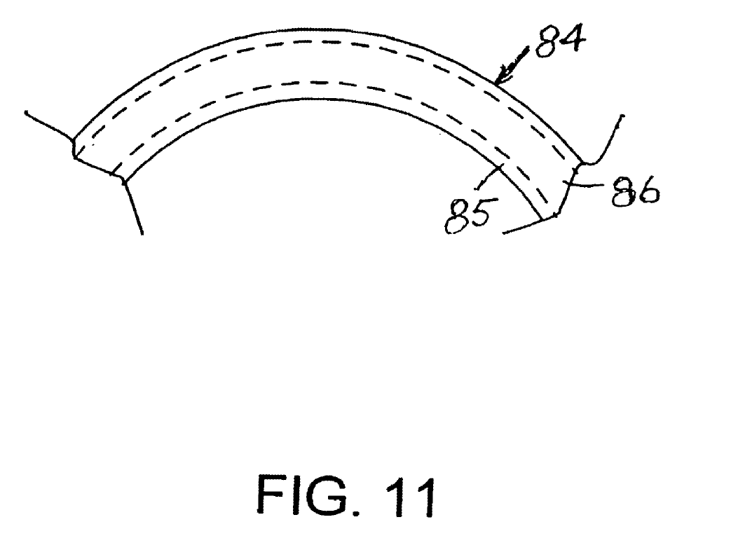

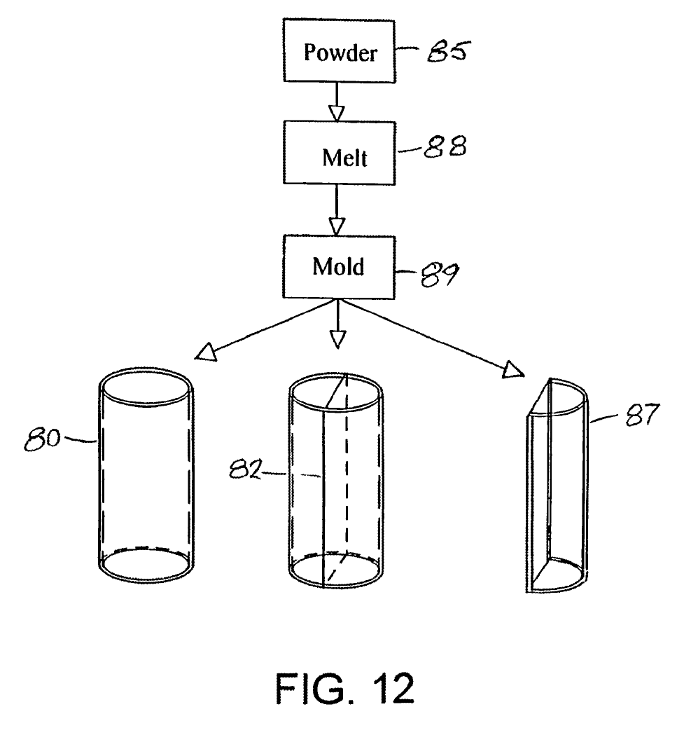

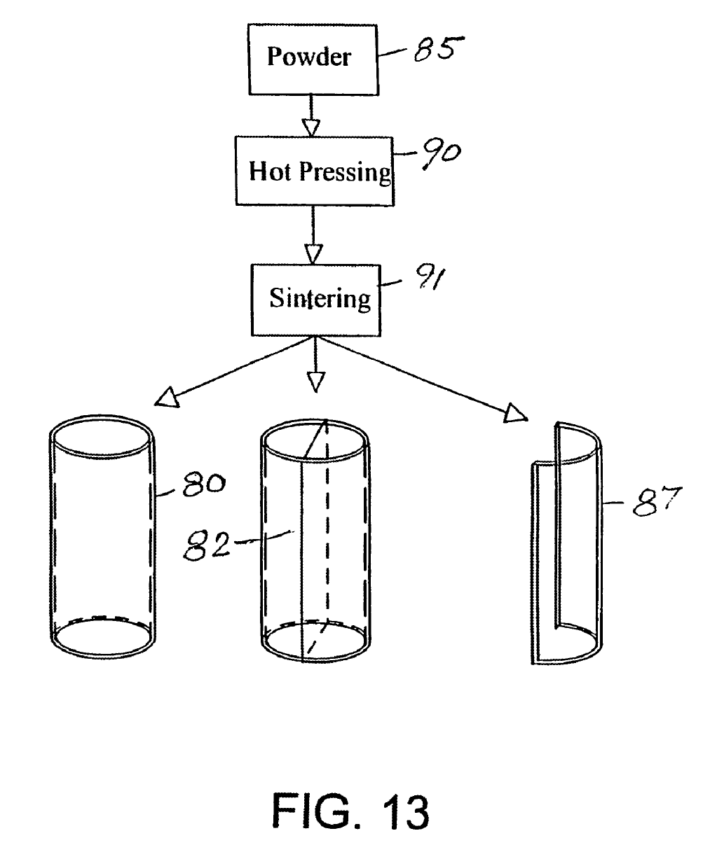

In FIGS. 8, 9, 10, 11, 12 and 13, a horizontal or vertical wafer processing boat preform 80 has a plurality of protrusions 81 for fabrication of slots for wafers and openings for gas flow between the wafers to enable even thickness deposition.

The wafer boat preform 80 may be made from silicon, silicon compound, silicon and germanium, SiₓGe₁₋ₓ, solid solution, silicon and Silicon-Carbide Siₓ(SiC)₁₋ₓ, Silicon and silicon dioxide Siₓ(SiO₂)₁₋ₓ, silicon and any ceramic, silicon and any oxide Siₓ(Oxide)₁₋ₓ, silicon and any metal SiₓM₁₋ₓ, Silicon and any alloy SiₓA₁₋ₓ, any combination between themselves, or made from composite material. In all cases 0≦x≦1.

The wafer boat preform may be made by layering one or more of the following materials: Siₓsilicon compound, SiₓGe₁₋ₓ, SiC, Siₓ(SiC)₁₋ₓ, Siₓ(SiO₂)₁₋ₓ, Siₓ(Oxide)₁₋ₓ, SiₓM₁₋ₓ, composite material, and any combination or order between themselves. In all cases, 0≦x≦1.

The wafer boat preform may have closed ends by a base and a top that may be half or full discs having outer diameters equal or greater than the outer diameter of the wafer boat.

The end disk might be a solid disk or may have certain portions removed.

The process fabricates a wafer boat preform from silicon, silicon compound, silicon and germanium, SiₓGe₁₋ₓ, solid solution, silicon and Silicon Carbide Siₓ(SiC)₁₋ₓ, Silicon and silicon dioxide Siₓ(SiO₂)₁₋ₓ, silicon and any ceramic, silicon and any oxide Siₓ(Oxide)₁₋ₓ, silicon and any metal SiₓM₁₋ₓ, Silicon and any alloy SiₓA₁₋ₓ, any combination between themselves, or made from composite material (in all cases 0≦x≦1), by heating and melting the boat material within a mold having a desired shape and form, or transferring it to the mold, solidifying it, cooling it down at a desired cool-down regime, and machining it to the desired tolerance.

The boat fabrication material can be powder.

The boat fabrication material can be solid material.

The melting is done in a vacuum chamber.

The melting is done under reduced or high pressure of inert or reactive gas.

The reactive gas is a mixture between atomic or charged molecular state gas such as plasma gas and a neutral inert or reactive gas.

The sintering and/or melting is preceded by one or more steps of purging and purification.

Wafer boat preforms consist of silicon, silicon compound, silicon and germanium, SiₓGe₁₋ₓ solid solution, silicon and Silicon Carbide Siₓ(SiC)₁₋ₓ, Silicon and silicon dioxide Siₓ(SiO₂)₁₋ₓ, silicon and any ceramic, silicon and any oxide Siₓ(Oxide)₁₋ₓ, silicon and any metal SiₓM₁₋ₓ, Silicon and any alloy SiₓA₁₋ₓ, any combination between themselves, or made from composite material (in all cases 0≦x≦1), by pressing the boat material within a die having desired shape and form, sintering, cooling it down at a desired cool-down regime, and machining it to the desired tolerance. The boat fabrication material is powder. The boat fabrication material is solid material. The pressing is done in a vacuum chamber. The pressing is done under reduced or high pressure of inert or reactive gas. The reactive gas is mixture between atomic or charged molecular state gas such as plasma gas and a neutral inert or reactive gas.

The melting is preceded by one or more steps of purging and purification.

The process fabricates wafer boat preforms including silicon, silicon compound, silicon and germanium, SiₓGe₁₋ₓ solid solution, silicon and Silicon Carbide Siₓ(SiC)₁₋ₓ, Silicon and silicon dioxide Siₓ(SiO₂)₁₋ₓ, silicon and any ceramic, silicon and any oxide Siₓ(Oxide)₁₋ₓ, silicon and any metal SiₓM₁₋ₓ, Silicon and any alloy SiₓA₁₋ₓ, any combination between themselves, or made from a composite material (in all cases 0≦x≦1), by extruding the boat material within a die having desired shape and form, sintering, cooling it down at a desired cool-down regime, and machining it to the desired tolerance. The boat fabrication material is powder. The boat fabrication material is powder mixed with organic or inorganic material, or the boat fabrication material is solid material. The pressing is done in a vacuum chamber. The pressing is done under reduced or high pressure of inert or reactive gas. The reactive gas is mixture between atomic or charged molecular state gas such as plasma gas and a neutral inert or reactive gas. The melting is preceded by one or more steps of purging and purification.

The invention provides processes for fabrication of a member having the shape of a tube, plate, rod, or any other shape from silicon, silicon compound including but not limited to SiN, Si₃N₄, SiON, and/or the like, silicon and germanium, SiₓGe₁₋ₓ solid solution, silicon and Silicon Carbide Siₓ(SiC)₁₋ₓ, Silicon and silicon dioxide Siₓ(SiO₂)₁₋ₓ, silicon and any ceramic, silicon and any oxide Siₓ(Oxide)₁₋ₓ, silicon and any metal SiₓM₁₋ₓ, Silicon and any alloy SiₓA₁₋ₓ, any combination between themselves, or made from a composite material (in all cases 0≦x≦1), by heating and melting the member material within a mold having desired shape and form, or transferring it to the mold, solidifying it, cooling it down at a desired cool-down regime, and machining it to the desired tolerance. The member fabrication material is powder, or the member fabrication material is solid material.

The process is done in a reduced pressure chamber.

The melting is done under reduced or high pressure of inert or reactive gas. The reactive gas is mixture between atomic or charged molecular state gas such as plasma gas and a neutral inert or reactive gas. The melting is preceded by one or more steps of purging and purification.

The new process provides for fabrication of members having the shape of a tube, a plate, a rod, or any other shape from silicon, silicon and germanium, SiₓGe₁₋ₓ solid solution, silicon and Silicon Carbide Siₓ(SiC)₁₋ₓ, Silicon and silicon dioxide Siₓ(SiO₂)₁₋ₓ, silicon and any ceramic, silicon and any oxide Siₓ(Oxide)₁₋ₓ, silicon and any metal SiₓM₁₋ₓ, Silicon and any alloy SiₓA₁₋ₓ, any combination between themselves, or made from composite material (in all cases 0≦x≦1), by pressing the member material within a die having desired shape and form, sintering, cooling it down at a desired cool-down regime, and machining it to the desired tolerance. The member fabrication material is powder, or the member fabrication material is solid material. The pressing is done in a vacuum chamber. The pressing is done under reduced or high pressure of inert or reactive gas.

The reactive gas is a mixture between atomic or charged molecular state gas such as plasma gas and a neutral inert or reactive gas. The melting is preceded by one or more steps of purging and purification.

The new process provides for fabrication of a member having the shape of a tube, a plate, a rod, or any other shape from silicon, silicon compound including but not limited to SiN, Si₃N₄, SiON, and/or the like, silicon and germanium, SiₓGe₁₋ₓ solid solution, silicon and Silicon Carbide Siₓ(SiC)₁₋ₓ, Silicon and silicon dioxide Siₓ(SiO₂)₁₋ₓ, silicon and any ceramic, silicon and any oxide Siₓ(Oxide)₁₋ₓ, silicon and any metal SiₓM₁₋ₓ, Silicon and any alloy SiₓA₁₋ₓ any combination between themselves, or made from a composite material (in all cases 0≦x≦1), by extruding the member material within a die having a desired shape and form, sintering, cooling it down at a desired cool-down regime, and machining it to the desired tolerance.

The member fabrication material is powder.

The member fabrication material is powder mixed with organic or inorganic material.

The member fabrication material is solid material.

The pressing is done in a vacuum chamber.

The pressing is done under reduced or high pressure of inert and/or reactive gas.

The reactive gas is mixture between atomic or charged molecular state gas such as plasma gas and a neutral inert or reactive gas.

The sintering may be preceded by one or more steps of purging and purification.

The melting is preceded by one or more steps of purging and purification.

The material may be made only by sintering and without melting.

The process cuts the preform or solidified boat 80 in two, along medial lines 82. Openings 83 are formed in the cylindrical walls 84. Deposited material 85 is coated and fused on top of base material 86. Two boats 87 result. The powder 85 is melted 88 or molded 89, or hot pressed 90 and sintered 91. Finally, slots 92 are formed in the inward ribs or extensions 81. Ends 93 of boats 87 may have complementary steps to connect boats end-to-end in an axial stack or row.

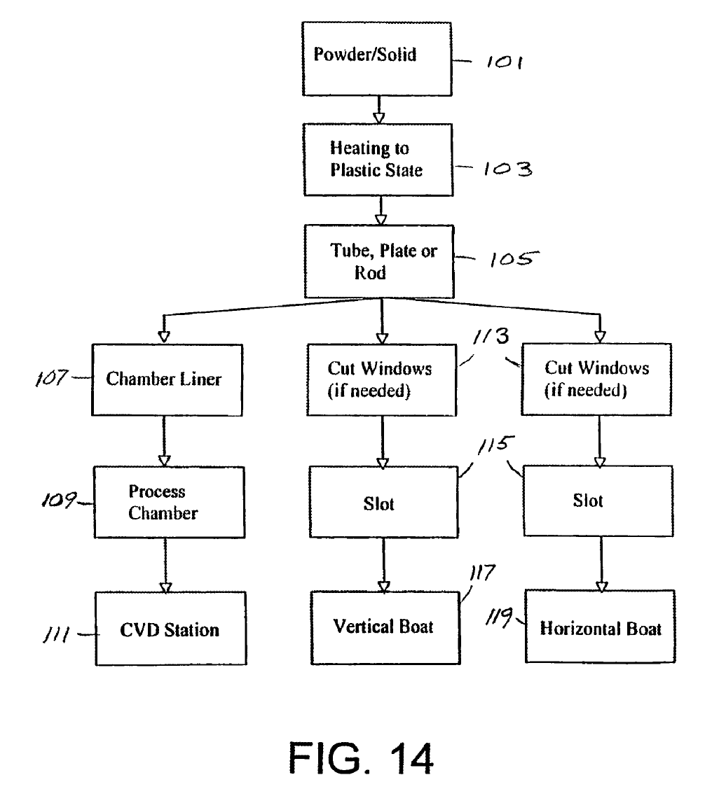

FIG. 14 shows steps of beginning with a powder or solid 101, heating 103 to a plastic slate, and forming 105 a tube, plate or rod. A chamber liner 107 is formed and applied to a process chamber 109, forming a chemical vapor deposition (CVD) station 111. Formed tubes 105 are halved lengthwise. Windows are cut 113. Inward ribs or extensions or the inner walls are slotted 115, forming a vertical boat 117. In parallel steps, windows are cut 113. The boat is slotted 115 and a horizontal boat 119 is formed.

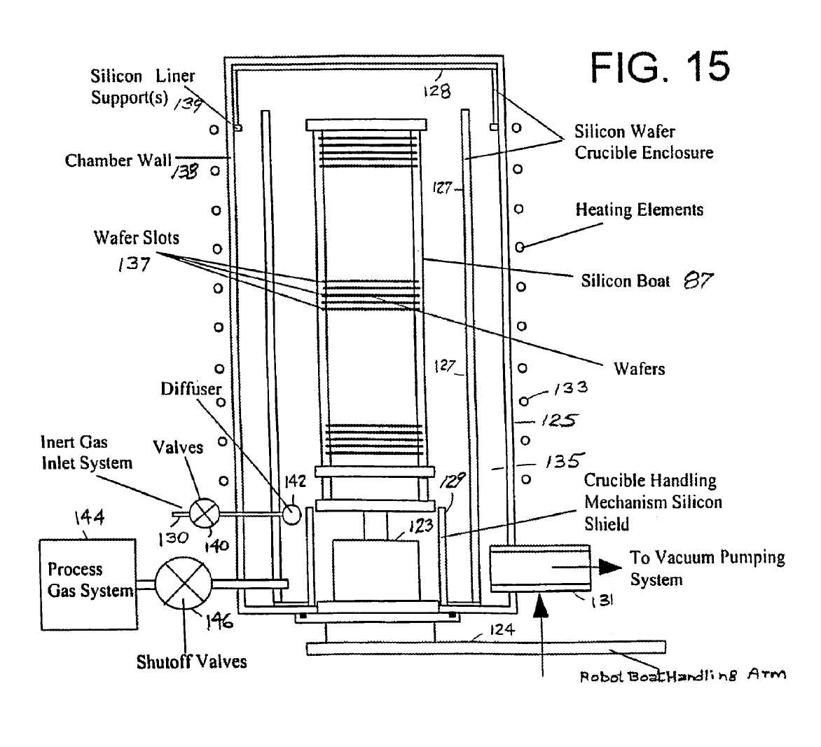

In FIG. 15, wafer processing apparatus 120 includes of a process chamber 121, wafer handling tools, wafer boat handling tools 123, 124, including one or more processing chambers 127, 128, shields 125 and enclosures 129 employing one or more members including silicon, silicon and germanium, SiₓGe₁₋ₓ solid solution, silicon and Silicon Carbide Siₓ(SiC)₁₋ₓ, Silicon and silicon dioxide Siₓ(SiO₂)₁₋ₓ, silicon and any ceramic, silicon and any oxide Siₓ(Oxide)₁₋ₓ, silicon and any metal SiₓM₁₋ₓ, Silicon and any alloy SiₓA₁₋ₓ, any combination between themselves, or made from composite material (in all cases 0≦x≦1). Each chamber may be equipped with separate or common gas delivery and venting system 130, vacuum system 131, internal or external heating elements 133, cooled or not cooled vacuum shell 135, partially or fully lined with silicon, silicon and germanium, SiₓGe₁₋ₓ solid solution, silicon and Silicon Carbide Siₓ(SiC)₁₋ₓ, Silicon and silicon dioxide Siₓ(SiO₂)₁₋ₓ, silicon and any ceramic, silicon and any oxide Siₓ(Oxide)₁₋ₓ, silicon and any metal SiₓM₁₋ₓ, Silicon and any alloy SiₓA₁₋ₓ, any combination between themselves, or made from a composite material (in all cases 0≦x≦1).

At least one of the processing chambers may be a CVD chamber employing one or more members from silicon, silicon and germanium, SiₓGe₁₋ₓ solid solution, silicon and Silicon Carbide Siₓ(SiC)₁₋ₓ, Silicon and silicon dioxide Siₓ(SiO₂)₁₋ₓ, silicon and any ceramic, silicon and any oxide Siₓ(Oxide)₁₋ₓ, silicon and any metal SiₓM₁₋ₓ, Silicon and any alloy SiₓA₁₋ₓ, any combination between themselves, or made from a composite material (in all cases 0≦x≦1). The CVD chamber may be equipped with separate or common gas delivery and venting system, vacuum system, internal or external heating elements, cooled or not cooled vacuum shell partially or fully lined with silicon, silicon and germanium, SiₓGe₁₋ₓ solid solution, silicon and Silicon Carbide Siₓ(SiC)₁₋ₓ, Silicon and silicon dioxide Siₓ(SiO₂)₁₋ₓ, silicon and any ceramic, silicon and any oxide Siₓ(Oxide)₁₋ₓ, silicon and any metal SiₓM₁₋ₓ, Silicon and any alloy SiₓA₁₋ₓ, any combination between themselves, or made from a composite material (in all cases 0≦x≦1).

At least one of the processing chambers may be an epitaxial chamber employing one or more members including silicon, silicon and germanium, SiₓGe₁₋ₓ solid solution, silicon and Silicon Carbide Siₓ(SiC)₁₋ₓ, Silicon and silicon dioxide Siₓ(SiO₂)₁₋ₓ, silicon and any ceramic, silicon and any oxide Siₓ(Oxide)₁₋ₓ, silicon and any metal SiₓM₁₋ₓ, Silicon and any alloy SiₓA₁₋ₓ, any combination between themselves, or made from composite material (in all cases 0≦x≦1). The epitaxial chamber may be equipped with separate or common gas delivery and venting system, vacuum system, internal or external heating elements, cooled or not cooled vacuum shell partially or fully lined with silicon, silicon and germanium, SiₓGe₁₋ₓ, solid solution, silicon and Silicon Carbide Siₓ(SiC)₁₋ₓ Silicon and silicon dioxide Siₓ(SiO₂)₁₋ₓ, silicon and any ceramic, silicon and any oxide Siₓ(Oxide)₁₋ₓ, silicon and any metal SiₓM₁₋ₓ, Silicon and any alloy SiₓA₁₋ₓ, any combination between themselves, or made from a composite material (in all cases 0≦x≦1).

At least one of the processing chambers may be a thin film deposition chamber employing one or more members formed of silicon, silicon and germanium, SiₓGe₁₋ₓ solid solution, silicon and Silicon Carbide Siₓ(SiC)₁₋ₓ, Silicon and silicon dioxide Siₓ(SiO₂)₁₋ₓ, silicon and any ceramic, silicon and any oxide Siₓ(Oxide)₁₋ₓ, silicon and any metal SiₓM₁₋ₓ, Silicon and any alloy SiₓA₁₋ₓ, any combination between themselves, or made from a composite material (in all cases 0≦x≦1). The thin film deposition chamber may be equipped with separate or common gas delivery and venting system, vacuum system, internal or external heating elements, cooled or not cooled vacuum shell partially or fully lined with silicon, silicon and germanium, SiₓGe₁₋ₓ solid solution, silicon and Silicon Carbide Siₓ(SiC)₁₋ₓ, Silicon and silicon dioxide Siₓ(SiO₂)₁₋ₓ, silicon and any ceramic, silicon and any oxide Siₓ(Oxide)₁₋ₓ, silicon and any metal SiₓM₁₋ₓ, Silicon and any alloy SiₓA₁₋ₓ, any combination between themselves, or made from a composite material (in all cases 0≦x≦1).

At least one of the processing chambers may be a thin film removal chamber employing one or more members formed of silicon, silicon and germanium, SiₓGe₁₋ₓ solid solution, silicon and Silicon Carbide Siₓ(SiC)₁₋ₓ, Silicon and silicon dioxide Siₓ(SiO₂)₁₋ₓ, silicon and any ceramic, silicon and any oxide Siₓ(Oxide)₁₋ₓ, silicon and any metal SiₓM₁₋ₓ, Silicon and any alloy SiₓA₁₋ₓ, any combination between themselves, or made from a composite material (in all cases 0≦x≦1). The thin film removal chamber may be equipped with a separate or a common gas delivery and venting system, vacuum system, internal or external heating elements, cooled or not cooled vacuum shell partially or fully lined with silicon, silicon and germanium, SiₓGe₁₋ₓ solid solution, silicon and Silicon Carbide Siₓ(SiC)₁₋ₓ, Silicon and silicon dioxide Siₓ(SiO₂)₁₋ₓ, silicon and any ceramic, silicon and any oxide Siₓ(Oxide)₁₋ₓ, silicon and any metal SiₓM₁₋ₓ, Silicon and any alloy SiₓA₁₋ₓ, any combination between themselves, or made from a composite material (in all cases 0≦x≦1).

One of the chambers may be a main chamber connected with other chambers directly or via one or more gate valves.

One or more chambers may be vacuum, low pressure or desired pressure chamber.

One or more chambers may have at least one internal or external heater.

One or more chambers may have at least one partial or complete heat shield.

Wafer processing apparatus includes at least one CVD chamber, employing one or more members formed of silicon, silicon and germanium, SiₓGe₁₋ₓ, solid solution, silicon and Silicon Carbide Siₓ(SiC)₁₋ₓ, Silicon and silicon dioxide Siₓ(SiO₂)₁₋ₓ, silicon and any ceramic, silicon and any oxide Siₓ(Oxide)₁₋ₓ, silicon and any metal SiₓM₁₋ₓ, Silicon and any alloy SiₓA₁₋ₓ, any combination between themselves, or made from a composite material (in all cases 0≦x≦1). The CVD chamber may be equipped with a separate or a common gas delivery and venting system, vacuum system, internal or external heating elements, cooled or not cooled vacuum shell partially or fully lined with silicon, silicon and germanium, SiₓGe₁₋ₓ solid solution, silicon and Silicon Carbide Siₓ(SiC)₁₋ₓ, Silicon and silicon dioxide Siₓ(SiO₂)₁₋ₓ, silicon and any ceramic, silicon and any oxide Siₓ(Oxide)₁₋ₓ, silicon and any metal SiₓM₁₋ₓ, Silicon and any alloy SiₓA₁₋ₓ, any combination between themselves, or made from a composite material (in all cases 0≦x≦1).

At least one CVD chamber may be connected with other chambers or with a main wafer distribution chamber directly or via one or more gate valves.

At least one CVD chamber may be vacuum, low pressure or desired pressure chamber.

At least one CVD chamber may have at least one internal or external heater.

At least one CVD chamber may have at least one partial or complete heat shield.

Wafer processing apparatus includes at least one epitaxial chamber employing one or more members formed of silicon, silicon and germanium, SiₓGe₁₋ₓ solid solution, silicon and Silicon Carbide Siₓ(SiC)₁₋ₓ, Silicon and silicon dioxide Siₓ(SiO₂)₁₋ₓ, silicon and any ceramic, silicon and any oxide Siₓ(Oxide)₁₋ₓ, silicon and any metal SiₓM₁₋ₓ, Silicon and any alloy SiₓA₁₋ₓ, any combination between themselves, or made from a composite material (in all cases 0≦x≦1). The epitaxial chamber may be equipped with a separate or a common gas delivery and venting system, vacuum system, internal or external heating elements, cooled or not cooled vacuum shell partially or fully lined with silicon, silicon and germanium, SiₓGe₁₋ₓ, solid solution, silicon and Silicon Carbide Siₓ(SiC)₁₋ₓ, Silicon and silicon dioxide Siₓ(SiO₂)₁₋ₓ, silicon and any ceramic, silicon and any oxide Siₓ(Oxide)₁₋ₓ, silicon and any metal SiₓM₁₋ₓ, Silicon and any alloy SiₓA₁₋ₓ any combination between themselves, or made from a composite material (in all cases 0≦x≦1.

At least one epitaxial chamber may be connected with other chambers or with a main wafer distribution chamber directly or via one or more gate valves.

At least one epitaxial chamber may be vacuum, low pressure or desired pressure chamber.

At least one epitaxial chamber may have at least one internal or external heater.

At least one epitaxial chamber may have at least one partial or complete heat shield.

Wafer processing apparatus includes at least one thin film deposition chamber employing one or more members formed of silicon, silicon and germanium, SiₓGe₁₋ₓ solid solution, silicon and Silicon Carbide Siₓ(SiC)₁₋ₓ, Silicon and silicon dioxide Siₓ(SiO₂)₁₋ₓ, silicon and any ceramic, silicon and any oxide Siₓ(Oxide)₁₋ₓ, silicon and any metal SiₓM₁₋ₓ, Silicon and any alloy SiₓA₁₋ₓ, any combination between themselves, or made from a composite material (in all cases 0≦x≦1). The thin film deposition chamber may be equipped with a separate or a common gas delivery and venting system, vacuum system, internal or external heating elements, cooled or not cooled vacuum shell partially or fully lined with silicon, silicon and germanium, SiₓGe₁₋ₓ solid solution, silicon and Silicon Carbide Siₓ(SiC)₁₋ₓ, Silicon and silicon dioxide Siₓ(SiO₂)₁₋ₓ, silicon and any ceramic, silicon and any oxide Siₓ(Oxide)₁₋ₓ, silicon and any metal SiₓM₁₋ₓ Silicon and any alloy SiₓA₁₋ₓ, any combination between themselves, or made from a composite material (in all cases 0≦x≦1).

At least one thin film deposition chamber may be connected with other chambers or with a main wafer distribution chamber directly or via one or more gate valves.

At least one thin film deposition chamber may be vacuum, low pressure or desired pressure chamber.

At least one thin film deposition chamber may have at least one internal or external heater.

At least one thin film deposition chamber may have at least one partial or complete heat shield.

Wafer processing apparatus includes at least one thin film removal chamber employing one or more members formed of silicon, silicon and germanium, SiₓGe₁₋ₓ solid solution, silicon and Silicon Carbide Siₓ(SiC)₁₋ₓ, Silicon and silicon dioxide Siₓ(SiO₂)₁₋ₓ, silicon and any ceramic, silicon and any oxide Siₓ(Oxide)₁₋ₓ, silicon and any metal SiₓM₁₋ₓ, Silicon and any alloy SiₓA₁₋ₓ, any combination between themselves, or made from a composite material (in all cases 0≦x≦1). The thin film removal chamber may be equipped with a separate or a common gas delivery and venting system, vacuum system, internal or external heating elements, cooled or not cooled vacuum shell partially or fully lined with silicon, silicon and germanium, SiₓGe₁₋ₓ solid solution, silicon and Silicon Carbide Siₓ(SiC)₁₋ₓ, Silicon and silicon dioxide Siₓ(SiO₂)₁₋ₓ, silicon and any ceramic, silicon and any oxide Siₓ(Oxide)₁₋ₓ, silicon and any metal SiₓM₁₋ₓ Silicon and any alloy SiₓA₁₋ₓ, any combination between themselves, or made from a composite material (in all cases 0≦x≦1).

At least one thin film removal chamber may be connected with other chambers or with a main wafer distribution chamber directly or via one or more gate valves.

At least one thin film removal chamber may be vacuum, low pressure or desired pressure chamber.

At least one thin film removal-chamber may have at least one internal or external heater.

At least one thin film removal chamber may have at least one partial or complete heat shield.

A chemical vapor deposition (CVD) system includes a vacuum vessel with cooled or not cooled chamber with a single or double wall, a robot handling arm having appropriate elements for wafer or wafer boat delivery/removal that forms a vacuum tight seal when the chamber is loaded, a wafer tray/boat containing one or more wafers resting on the wafer boat delivery/removal arm, a shield surrounding the wafer tray/boat and the inside portion of the wafer handling arm, process gas delivery system with all appropriate valves attached to the chamber and having a delivery tube extending into wafer area, inert gas delivery system with all appropriate valves attached to the chamber and having an delivery tube with or without a diffuser extending into a wafer area, a vacuum pumping system connected to the chamber, an inside or outside heater directing heat into the process area employing one or more members formed of silicon, silicon and germanium, SiₓGe₁₋ₓ solid solution, silicon and Silicon Carbide Siₓ(SiC)₁₋ₓ, Silicon and silicon dioxide Siₓ(SiO₂)₁₋ₓ, silicon and any ceramic, silicon and any oxide Siₓ(Oxide)₁₋ₓ, silicon and any metal SiₓM₁₋ₓ, Silicon and any alloy SiₓA₁₋ₓ, any combination between themselves, or made from a composite material (in all cases 0.1≦x≦1.)

The CVD system may be vertical, horizontal, or have any suitable position from −90 to +90.

The wafer boat may be formed of solid connected members made from silicon, silicon and germanium, SiₓGe₁₋ₓ solid solution, silicon and Silicon Carbide Siₓ(SiC)₁₋ₓ, Silicon and silicon dioxide Siₓ(SiO₂)₁₋ₓ, silicon and any ceramic, silicon and any oxide Siₓ(Oxide)₁₋ₓ, silicon and any metal SiₓM₁₋ₓ, Silicon and any alloy SiₓA₁₋ₓ, any combination between themselves, or made from a composite material (in all cases 0≦x≦1).

The wafer boat may be formed of modular elements made from silicon, silicon and germanium, SiₓGe₁₋ₓ solid solution, silicon and Silicon Carbide Siₓ(SiC)₁₋ₓ, Silicon and silicon dioxide Siₓ(SiO₂)₁₋ₓ, silicon and any ceramic, silicon and any oxide Siₓ(Oxide)₁₋ₓ, silicon and any metal SiₓM₁₋ₓ, Silicon and any alloy SiₓA₁₋ₓ, any combination between themselves, or made from a composite material (in all cases 0≦x≦1).

The wafer boat may contain one or more slots for wafers support spaced at appropriate distance.

The wafers in the boat may be positioned so there is no other material between the wafers other than vacuum or any gas present in the processing part of the chamber.

The wafer boat may have slots for the wafer support and susceptors between the wafers for improved temperature distribution over the wafer surface that results in more uniform deposited layer thickness and composition.

The susceptor in the boat may part of the wafer boat.

The susceptor in the boat may be inserted after the boat has been made or prior to or together with the wafer loading.

The boat may be modular.

Each module of the boat may contain support for one or more wafers.

Each module may contain support for one or more wafers separated by inserted or built in susceptors.

The susceptor may be a full body or may have certain cuts to allow wafer only insertion/removal handling.

The boat may be made from modular parts connected via chemical or mechanical bonding.

The boat may have round, elliptical, polygonal or any other applicable cross section.

The boat may have one or more elements at each end for mechanical strength during handling.

The end parts of the boat may be modules.

All parts of the boat may be made from same or different materials.

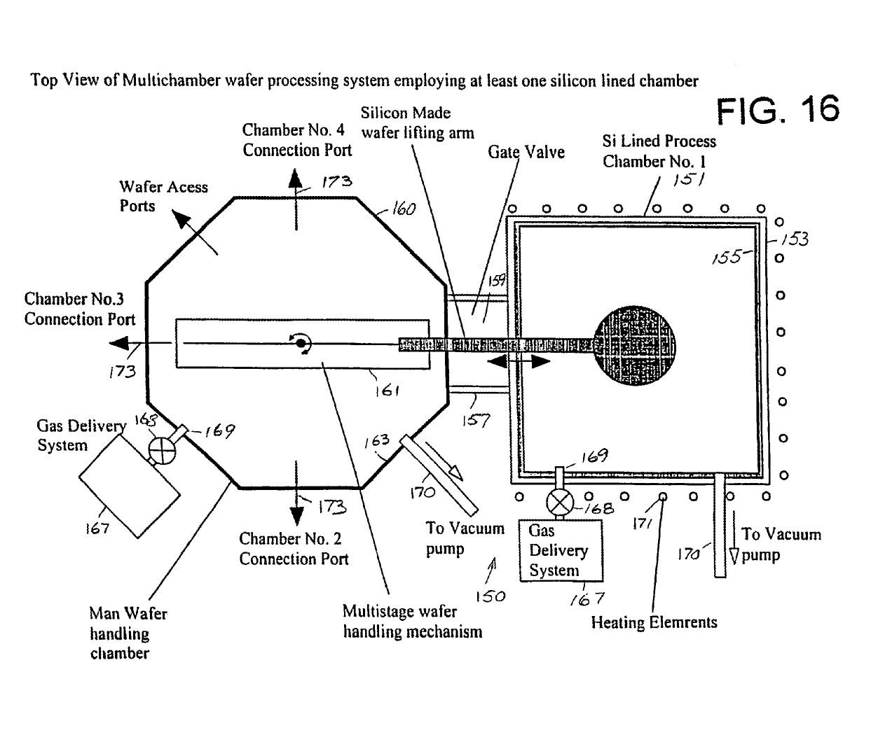

In FIG. 16, a single wafer processing system 150 for CVD, epitaxial deposition, thin film deposition/removal or any other wafer processing the chip requires system includes a vacuum vessel 151 with cooled or not cooled chamber wall 153 with single or double wall 155, connected directly 157 or through at least one gate valve 159 to a chamber 160 with a multistage wafer handling mechanism 161 for wafer delivery/removal, a shield 163 surrounding the wafer processing area, process and inert gas delivery system 165 with all appropriate valves 167 attached to the chamber 160 and having an delivery tube 169 extending into wafer area, vacuum pumping system 170 connected to the chamber 160, inside and/or outside heater directing heat into the process area employing one or more members including silicon, silicon and germanium, SiₓGe₁₋ₓ solid solution, silicon and Silicon Carbide Siₓ(SiC)₁₋ₓ, Silicon and silicon dioxide Siₓ(SiO₂)₁₋ₓ, silicon and any ceramic, silicon and any oxide Siₓ(Oxide)₁₋ₓ, silicon and any metal SiₓM₁₋ₓ, Silicon and any alloy SiₓA₁₋ₓ, any combination between themselves, or made from a composite material (in all cases 0≦x≦1).

Similar vacuum pumping systems 170 and gas delivery systems 167 may be used with both chambers. Heating elements 171 may be located around or in the chambers 151 and 160. Chamber connection ports 173 are provided to connect chamber 160 to additional chambers for transferring or removing the wafers.

The process chamber may be a CVD chamber.

The process chamber may be an epitaxial deposition chamber.

The process chamber may be a thin film deposition/removal chamber.

The process chamber may be any wafer process chamber.

The chamber may have any cross section and height and the system may be vertical, horizontal, or have any suitable position from −90 to +90.

The members are made from silicon, silicon and germanium, SiₓGe₁₋ₓ solid solution, silicon and Silicon Carbide Siₓ(SiC)₁₋ₓ, Silicon and silicon dioxide Siₓ(SiO₂)₁₋ₓ, silicon and any ceramic, silicon and any oxide Siₓ(Oxide)₁₋ₓ, silicon and any metal SiₓM₁₋ₓ, Silicon and any alloy SiₓA₁₋ₓ, any combination between themselves, or made from a composite material (in all cases 0≦x≦1) and may be solidly connected by means of chemical or mechanical bonding.

The members are made from silicon, silicon and germanium, SiₓGe₁₋ₓ solid solution, silicon and Silicon Carbide Siₓ(SiC)₁₋ₓ, Silicon and silicon dioxide Siₓ(SiO₂)₁₋ₓ, silicon and any ceramic, silicon and any oxide Siₓ(Oxide)₁₋ₓ, silicon and any metal SiₓM₁₋ₓ, Silicon and any alloy SiₓA₁₋ₓ, any combination between themselves, or made from a composite material (in all cases 0≦x≦1) and may be modular.

The members are made from silicon, silicon and germanium, SiₓGe₁₋ₓ solid solution, silicon and Silicon Carbide Siₓ(SiC)₁₋ₓ, Silicon and silicon dioxide Siₓ(SiO₂)₁₋ₓ, silicon and any ceramic, silicon and any oxide Siₓ(Oxide)₁₋ₓ, silicon and any metal SiₓM₁₋ₓ, Silicon and any alloy SiₓA₁₋ₓ, any combination between themselves, or made from a composite material (in all cases 0≦x≦1) and may contain one or more slots for wafers' support to optimize the process.

The wafer processing chamber may have a susceptor next to the wafer for improved temperature distribution over the wafer surface that results in more uniform deposited layer thickness and composition.

The susceptor in the process chamber may be part of the chamber.

The wafer delivery arm may be made in full or partially from silicon, silicon and germanium, SiₓGe₁₋ₓ solid solution, silicon and Silicon Carbide Siₓ(SiC)₁₋ₓ, Silicon and silicon dioxide Siₓ(SiO₂)₁₋ₓ, silicon and any ceramic, silicon and any oxide Siₓ(Oxide)₁₋ₓ, silicon and any metal SiₓM₁₋ₓ, Silicon and any alloy SiₓA₁₋ₓ, any combination between themselves, or made from a composite material (in all cases 0≦x≦1)

The susceptor may be full body or may have certain cuts to allow wafer only insertion/removal handling.

The chamber parts may be made in full or partially from silicon, silicon and germanium, SiₓGe₁₋ₓ solid solution, silicon and Silicon Carbide Siₓ(SiC)₁₋ₓ, Silicon and silicon dioxide Siₓ(SiO₂)₁₋ₓ, silicon and any ceramic, silicon and any oxide Siₓ(Oxide)₁₋ₓ, silicon and any metal SiₓM₁₋ₓ, Silicon and any alloy SiₓA₁₋ₓ, any combination between themselves, or made from composite material (in all cases 0≦x≦1) and they may be made from modular parts connected via chemical or mechanical bonding or by assembling them without bonding.

The chamber may have round, elliptical, polygonal or any other applicable cross section.

The end parts of the wafer processing chamber may be modules. All parts of the boat may be made from the same or different materials.

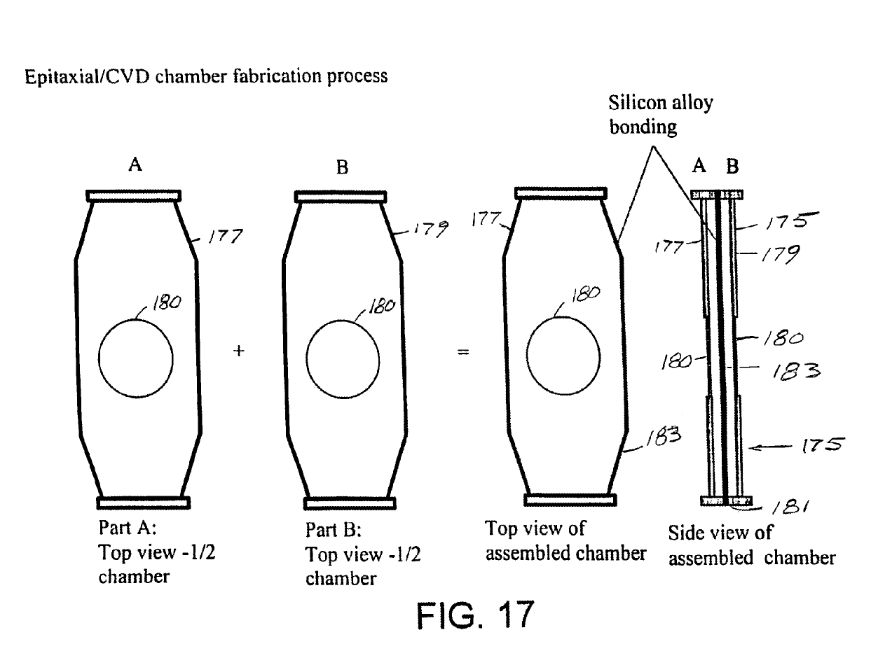

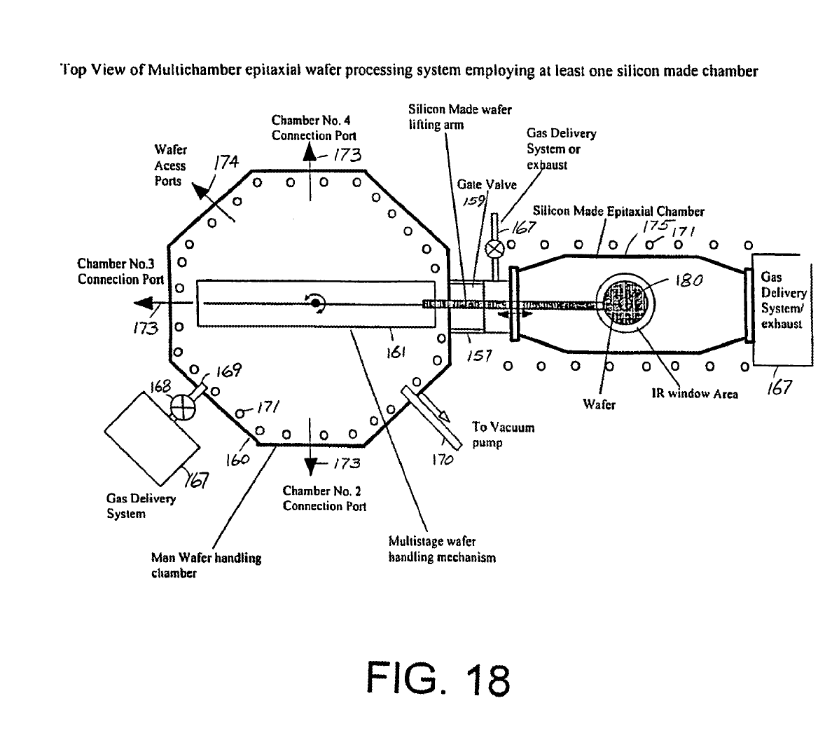

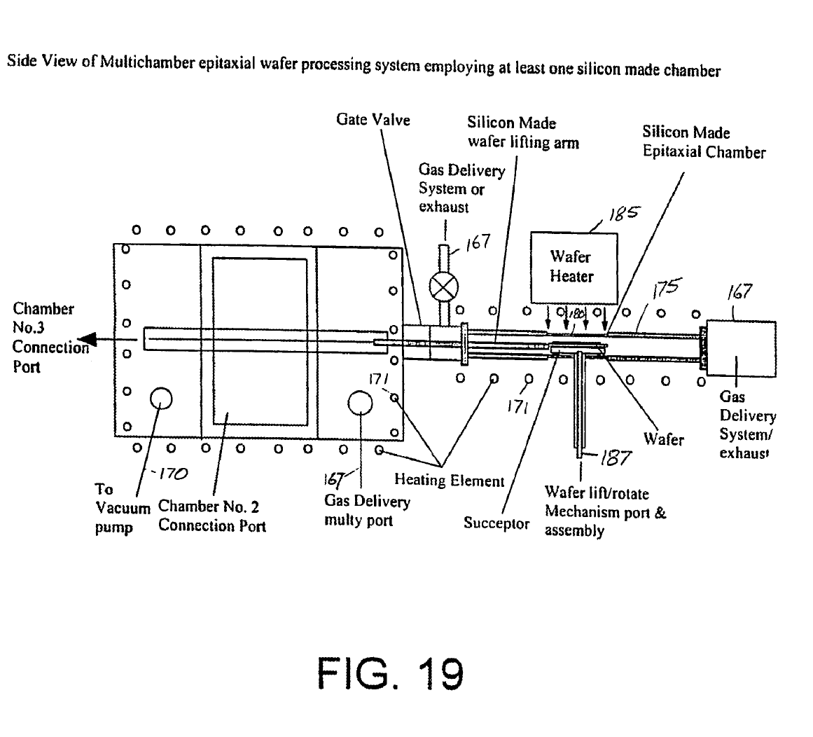

FIG. 17-19 show epitaxial/CVD chambers 175 made in full or partially from silicon, silicon and germanium, SiₓGe₁₋ₓ solid solution, silicon and Silicon Carbide Siₓ(SiC)₁₋ₓ, Silicon and silicon dioxide Siₓ(SiO₂)₁₋ₓ, silicon and any ceramic, silicon and any oxide Siₓ(Oxide)₁₋ₓ, silicon and any metal SiₓM₁₋ₓ, Silicon and any alloy SiₓA₁₋ₓ, any combination between themselves, or made from a composite material (in all cases 0≦x≦1) having a body 177, 179, an optical window 180 for wafer radiation and at least one opening 181 for wafer and gas delivery/removal. The bodies are bonded together along side edges 183 forming the chamber 175. A wafer heater 185 accesses wafers in chamber 175 through one window 180. A wafer lifting and rotating mechanism port and assembly 187 supports wafers through the opposite window.

Epitaxial chambers have suitable wall thickness and at least one infrared window at each side, a hollow interior, and at least one gate opening for connection to a wafer supply and process gas supply chamber, and a gas exhaust is made from silicon, silicon and germanium, SiₓGe₁₋ₓ solid solution, silicon and Silicon Carbide Siₓ(SiC)₁₋ₓ, Silicon and silicon dioxide Siₓ(SiO₂)₁₋ₓ, silicon and any ceramic, silicon and any oxide Siₓ(Oxide)₁₋ₓ, silicon and any metal SiₓM₁₋ₓ, Silicon and any alloy SiₓA₁₋ₓ, any combination between themselves, or made from a composite material (in all cases 0≦x≦1).

The epitaxial chamber body may include a single body made by pressing of material, machining it from inside and out in its green state, purifying the body at a certain temperature by immersing it in a chemically reactive gas, plasma or liquid for certain period of time, sintering the body at appropriate temperature determined by its composition, and final machining of the body, if needed, to meet the specifications of the epitaxial deposition process. The finished body may be subjected to thin film deposition such as chemical vapor deposition, plasma enhanced deposition, or other suitable deposition method for better finish on the inside and outside.

The epitaxial chamber body may include a single body made by casting of the material, machining it from inside and out in its green state, purifying the body at a certain temperature by immersing it in a chemically reactive gas, plasma or liquid for certain period of time, sintering the body at appropriate temperature determined by its composition, and final machining of the body, if needed, to meet the specifications of the epitaxial deposition process. The finished body may be subjected to thin film deposition such as chemical vapor deposition, plasma enhanced deposition, or other suitable deposition method for better finish on the inside and outside.

The epitaxial chamber may include upper and lower part made by casting to shape the material, machining the parts, purifying the body at a certain temperature by immersing it in a chemically reactive gas, plasma or liquid for certain period of time, sintering the body at appropriate temperature determined by its composition, joining the parts by chemical and/or mechanical means, and final machining of the body, if needed, to meet the specifications of the epitaxial deposition process. The finished body may be subjected to thin film deposition such as chemical vapor deposition, plasma enhanced deposition, or other suitable deposition method for better finish on the inside and outside.

The epitaxial chamber may include upper and lower parts made by cold or hot pressing to shape to shape the material, machining the parts, purifying the body at a certain temperature by immersing it in a chemically reactive gas, plasma or liquid for certain period of time, sintering the body at appropriate temperature determined by its composition, joining the parts by chemical and/or mechanical means, and final machining of the body, if needed, to meet the specifications of the epitaxial deposition process. The finished body may be subjected to thin film deposition such as chemical vapor deposition, plasma enhanced deposition, or other suitable deposition method for better finish on the inside and outside.

The epitaxial chamber may include upper and lower parts made by cold or hot pressing of a block of the material, machining the chamber, purifying the body at a certain temperature by immersing it in a chemically reactive gas, plasma or liquid for certain period of time, sintering the body at appropriate temperature determined by its composition, joining the parts by chemical and/or mechanical means, and final machining of the body, if needed, to meet the specifications of the epitaxial deposition process. The finished body may be subjected to thin film deposition such as chemical vapor deposition, plasma enhanced deposition, or other suitable deposition method for better finish on the inside and outside.

The epitaxial chamber may include upper and lower parts made by cold or hot extrusion of a block or a desired shape of the material, machining the chamber, purifying the body at a certain temperature by immersing it in a chemically reactive gas, plasma or liquid for certain period of time, sintering the body at appropriate temperature determined by its composition, joining the parts by chemical and/or mechanical means, and final machining of the body, if needed, to meet the specifications of the epitaxial deposition process. The finished body may be subjected to thin film deposition such as chemical vapor deposition, plasma enhanced deposition, or other suitable deposition method for better finish on the inside and outside.

The epitaxial chamber may include upper and lower parts made by plasma spraying of the material, and forming a chamber to a desired shape, machining the chamber, purifying the body at a certain temperature by immersing it in a chemically reactive gas, plasma or liquid for certain period of time, sintering the body at appropriate temperature determined by its composition, joining the parts by chemical and/or mechanical means, and final machining of the body, if needed, to meet the specifications of the epitaxial deposition process. The finished body may be subjected to thin film deposition such as chemical vapor deposition, plasma enhanced deposition, or other suitable deposition method for better finish on the inside and outside.

The epitaxial chamber may include upper and lower parts made by spraying of organic or inorganic based slurry of the material and forming a chamber to a desired shape, machining the chamber, purifying the body at a certain temperature by immersing it in a chemically reactive gas, plasma or liquid for certain period of time, sintering the body at appropriate temperature determined by its composition, joining the parts by chemical and/or mechanical means, and final machining of the body, if needed, to meet the specifications of the epitaxial deposition process. The finished body may be subjected to thin film deposition such as chemical vapor deposition, plasma enhanced deposition, or other suitable deposition method for better finish on the inside and outside.

The chamber includes two separate halves joined at one plane followed by final machining.

The chamber includes a single body machined from a solid block material.

The chamber includes a single body made by a method of plasma spraying followed by final machining.

The chamber includes a single body made by a method of slurry spraying

The chamber includes a single body machined by a method of casting, forging, or extrusion, followed by final machining.

The chamber may be a vacuum, reduced pressure, or desired pressure chamber.

The chamber may have a liner for a vacuum, reduced pressure or desired pressure chamber for wafer processing applications.

The chamber may be modular pieces stacked on top of each other or bonded by mechanical or chemical means.

The optical window may be from same or suitable material stacked on the chamber or bonded by mechanical or chemical means.

The chamber may have one or more optical windows depending on the process requirements.

Gas delivery system 167 for delivering process and inert gases into the chamber may be attached to the chamber or to the chamber wall.

The gas delivery members exposed to the process atmosphere may be made from the chamber material or chamber lining material.

The wafer delivering/removing arm to/from the chamber may be made from the chamber material or chamber lining material.

The susceptor and any other member that either holds the wafer, surrounds the wafer from the sides, the top, or the bottom, as required by the process, may be made from the chamber material or chamber lining material.

A reduced pressure chamber surrounds an epitaxial/CVD chamber made in full or partially from silicon, silicon and germanium, SiₓGe₁₋ₓ solid solution, silicon and Silicon Carbide Siₓ(SiC)₁₋ₓ, Silicon and silicon dioxide Siₓ(SiO₂)₁₋ₓ, silicon and any ceramic, silicon and any oxide Siₓ(Oxide)₁₋ₓ, silicon and any metal SiₓM₁₋ₓ, Silicon and any alloy SiₓA₁₋ₓ, any combination between themselves, or made from composite material (in all cases 0≦x≦1) having a body, an optical window for wafer radiation and at least one opening for wafer and gas delivery/removal.

The outer chamber may be vacuum, reduced pressure, or desired pressure as required by the process.

The chamber may have one or more optical windows depending on the process requirements.

The chamber may have a gas delivery system for delivering process and inert gases into the chamber may attached to the chamber or to the chamber wall.

A single wafer processing system for CVD, epitaxial deposition, thin film deposition/removal, or any other wafer processing of the chip, includes a vacuum vessel with cooled or not cooled chamber wall with single or double wall, connected directly or through at least one gate valve to a chamber with multistage wafer handling mechanism for wafer delivery/removal, a shield surrounding the wafer processing area, a process and inert gas delivery system with all appropriate valves attached to the chamber and having an delivery tube extending into wafer area, a vacuum pumping system connected to the chamber, an inside and/or outside heater directing heat into the process area employing one or more members formed of silicon, silicon and germanium, SiₓGe₁₋ₓ solid solution, silicon and Silicon Carbide Siₓ(SiC)₁₋ₓ, Silicon and silicon dioxide Siₓ(SiO₂)₁₋ₓ, silicon and any ceramic, silicon and any oxide Siₓ(Oxide)₁₋ₓ, silicon and any metal SiₓM₁₋ₓ, Silicon and any alloy SiₓA₁₋ₓ, any combination between themselves, or made from a composite material (in all cases 0≦x≦1), employing at least one epitaxial chamber made by the method described herein.

While the invention has been described with reference to specific embodiments, modifications and variations of the invention may be constructed without departing from the scope of the invention, which is defined in the following claims.

I claim:

1. A process of manufacturing at least one electronic chip comprising:
(a) selecting a fabrication material from the group consisting of silicon,
silicon compound comprising at least one silicon atom and in which silicon is a majority,
silicon and germanium,
Siₓ₁Ge₁₋ₓ₁ solid solution, wherein 0≦X1≦1,
silicon and silicon carbide Siₓ₂(SiC)₁₋ₓ₂, wherein 0.3≦X2≦1,
silicon and silicon dioxide Siₓ₃(SiO₂)₁₋ₓ₃, wherein 0<X3<1,
silicon and a ceramic and in which silicon is the majority material,
silicon and an oxide Siₓ₄(Oxide)₁₋ₓ₄, wherein 0≦X4≦1,
silicon and a metal Siₓ₅M₁₋ₓ₅, wherein 0≦X5≦1,
silicon and a metal alloy Siₓ₆A₁₋ₓ₆, wherein 0≦X5≦1, and combinations thereof;
(b) forming at least a portion of a wafer processing chamber from the fabrication material using a process selected from the group consisting of forging, extrusion, plasma deposition, hot substrate powder deposition, powder deposition, CVD deposition, slurry spray, slurry processing, casting, gelcasting, directional solidification, crystal growth, powder processing, and combination thereof;
(c) placing a wafer in the chamber and on the wafer processing member at least for a period of time that the wafer is in the chamber;
(d) processing the wafer in the chamber;
(e) removing the wafer from the chamber; and
(f) processing the wafer to form at least one electronic chip comprising one or more electronic devices.

2. The process according to claim 1, wherein forming comprises:
pressing the fabrication material within a die having a desired shape and form;
sintering or melting the pressed fabrication material;
cooling down the sintered fabrication material at a desired cool-down regime; and
machining the cooled fabrication material to a desired tolerance.

3. The process according to claim 2, wherein melting or sintering is preceded by at least one of purging and purifying.

4. The process according to claim 2, wherein pressing comprises pressing under reduced or high pressure of inert or reactive gas.

5. The process according to claim 4, wherein the reactive gas comprises a mixture of atomic or charged molecular state gas, optionally plasma gas, and a neutral inert or reactive gas.

6. The process according to claim 1, wherein the fabrication material is powder, and further comprising organic compounds, inorganic compounds, or both, for shaping purposes.

7. The process according to claim 1, wherein forming comprises:
extruding the fabrication material through a die having a desired shape and form;
sintering the extruded fabrication material
cooling down the sintered fabrication material at a desired cool-down regime; and
machining the cooled fabrication material to a desired tolerance.

8. The process according to claim 1, wherein the fabrication material is powder.

9. The process according to claim 1, wherein forming comprises:
molding the fabrication material in a mold having a desired shape and form, and thereafter heating and melting or sintering the material; or
heating and melting or sintering the material, transferring the material to a mold, solidifying the material, cooling down the solidified material at a desired cool-down regime, removing the mold, machining the cooled down material to a desired tolerance, and sintering the cooled down material.

10. The process according to claim 9, wherein melting comprises melting in a vacuum chamber.

11. The process according to claim 9, wherein melting or sintering comprises melting or sintering under reduced or high pressure of inert and reactive gas.

12. The process according to claim 9, further comprising:
at least one of purging and purifying, before said melting or sintering.

13. The process according to claim 1, wherein forming comprises fabricating a wafer boat member.

14. The process according to claim 1, wherein forming comprises forming a chamber liner, and further comprising:
applying the chamber liner to a process chamber; and
forming a chemical vapor deposition (CVD) station with the process chamber.

15. The process according to claim 1, wherein forming comprises forming a tube from the fabrication material.

16. The process according to claim 15, wherein forming comprises fabricating a wafer boat member from said tube.

17. The process according to claim 16, further comprising:
cutting the wafer boat member in two along medial lines;
forming openings in cylindrical walls of said wafer boat member; and
coating and fusing a depositing material on top of the wafer boat member.

18. The process according to claim 17, further comprising:
forming, in the wafer boat member, inward ribs, outward ribs or extensions, or both, and forming slots in the ribs or extensions; or
forming, in the wafer boat member boat ends with complementary steps to permit connection of at least two boats end-to-end in an axial stack or row.
